(19) United States
(12) Patent Application Publication
(10) Pub. No.: US 2026/0361292 A1
(43) Pub. Date: Nov. 12, 2026

(54) PHASE SHIFTER AND ELECTRONIC DEVICE INCLUDING THE SAME

(71) Applicant: SAMSUNG ELECTRONICS CO., LTD., Suwon-si (KR)

(72) Inventors: GeonHo PARK, Suwon-si (KR); BYEONGTAEK MOON, Suwon-si (KR); HYUNCHUL PARK, Suwon-si (KR)

(73) Assignee: SAMSUNG ELECTRONICS CO., LTD., Suwon-si (KR)

(21) Appl. No.: 19/529,766

(22) Filed: Feb. 4, 2026

(30) Foreign Application Priority Data
May 8, 2025 (KR) 10-2025-0059872

(51) Int. Cl. H03H 11/46

(52) U.S. Cl. CPC H03H 11/46

(57) ABSTRACT

Provided is a phase shifter including a first generation circuit that outputs, from an input signal, a first signal having a first frequency response and a second signal having a second frequency response, the second signal orthogonal to the first signal, a first sub-circuit that outputs a first component signal having a first overlapping frequency response, in which the first frequency response is overlapped, based on the first signal, a second sub-circuit that outputs a second component signal having a second overlapping frequency response, in which the second frequency response is overlapped, based on the second signal, and an output combining circuit that combines the first component signal and the second component signal and outputs an output signal in which the first overlapping frequency response and the second overlapping frequency response are offset.

### CROSS-REFERENCE TO RELATED APPLICATIONS

This application claims priority under 35 U.S.C. § 119 to Korean Patent Application No. 10-2025-0059872 filed on May 8, 2025, in the Korean Intellectual Property Office, the disclosure of which is incorporated herein in its entirety by reference.

### BACKGROUND

Embodiments described herein relate to a phase shifter and an electronic device including the same.

Radar technology has been increasingly utilized in the fields of advanced driver assistance systems (ADAS), gesture recognition, and mobile applications. In particular, development of millimeter-wave radars that utilize signals in ultra-high frequency bands (e.g., 60 GHz or 82 GHz) is actively underway to achieve high distance resolution in the radar technology.

To mitigate the path loss of radio waves in the ultra-high frequency bands and to increase the transmission distance of radio waves in the ultra-high frequency bands beamforming, massive Multiple-Input Multiple-Output (MIMO), full-dimensional MIMO (FD-MIMO), array antennas, analog beamforming, and large-scale antenna technologies are being discussed in 5G communication systems.

In particular, to implement beamforming or MIMO technology, a vector sum phase shifting method of dividing an input signal into an I signal and a Q signal, controlling the magnitude and the phase of each of the I signal and Q signal, combining the controlled signals, and outputting a signal having the target phase and magnitude is utilized. To improve the resolution of a phase shifter utilizing the vector sum phase shifting method, development of a technology is required to reduce errors in the magnitude and the phase of each of the I signal and Q signal.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

Embodiments of the present disclosure provide a phase shifter capable of high-resolution phase control in a relatively wide frequency band.

According to one or more embodiments, a phase shifter includes a first generation circuit that outputs, from an input signal, a first signal having a first frequency response and a second signal having a second frequency response, the second signal orthogonal to the first signal, a first sub-circuit that outputs a first component signal having a first overlapping frequency response, in which the first frequency response is overlapped, based on the first signal, a second sub-circuit that outputs a second component signal having a second overlapping frequency response, in which the second frequency response is overlapped, based on the second signal, and an output combining circuit that combines the first component signal and the second component signal and outputs an output signal in which the first overlapping frequency response and the second overlapping frequency response are offset.

According to one or more embodiments, an operating method of a phase shifter includes generating, from an input signal input to a first generation circuit, a first signal having a first frequency response and a second signal having a second frequency response, the second signal being orthogonal to the first signal, generating a first component signal having a first overlapping frequency response, in which the first frequency response is overlapped, based on the first signal, generating a second component signal having a second overlapping frequency response, in which the second frequency response is overlapped, based on the second signal, and combining the first component signal and the second component signal and outputting an output signal in which the first overlapping frequency response and the second overlapping frequency response are offset.

According to one or more embodiments, a phase shifter includes a power divider circuit that divides power of an input signal and outputs a first input signal and a second input signal having the same phase, a first coupler circuit that outputs, from the first input signal, a first middle signal having a first frequency response and a second middle signal having a second frequency response, the second middle signal being orthogonal to the first middle signal, a second coupler circuit that outputs, from the second input signal, a third middle signal having the first frequency response and a fourth middle signal having the second frequency response, the fourth middle signal being orthogonal to the third middle signal, a third coupler circuit that outputs, from the first middle signal and the second middle signal, a first combination signal having an offset frequency response in which the first frequency response and the second frequency response are offset, a fourth coupler circuit that outputs a second combination signal having the offset frequency response from the third middle signal and the fourth middle signal, and a power combiner that combines the first combination signal and the second combination signal and outputs an output signal.

### BRIEF DESCRIPTION OF DRAWINGS

The above and other objects and features of the present disclosure will become apparent by describing in detail embodiments thereof with reference to the accompanying drawings.

FIG. 1 is a block diagram illustrating an electronic device, according to one or more embodiments.

FIG. 2 is a block diagram showing a phase shifter, according to one or more embodiments.

FIG. 3A is a circuit diagram showing an example of a first generation circuit in a phase shifter.

FIG. 3B is a circuit diagram showing another example of a first generation circuit in a phase shifter.

FIG. 4A is a graph showing a first frequency response and a second frequency response, according to one or more embodiments.

FIG. 4B is a graph showing a first overlapping frequency response and an offset frequency response, according to one or more embodiments.

FIG. 4C is a graph showing a second overlapping frequency response and an offset frequency response, according to one or more embodiments.

FIG. 5 is a circuit diagram showing a phase shifter, according to one or more embodiments.

FIG. 6A illustrates a configuration for outputting a first component signal from a third signal and a fourth signal when a phase shifter operates at a first frequency, according to one or more embodiments.

FIG. 6B illustrates a configuration for outputting a second component signal from a fifth signal and a sixth signal when a phase shifter operates at a first frequency, according to one or more embodiments.

FIG. 6C illustrates a configuration for outputting an output signal from a first component signal and a second component signal when a phase shifter operates at a first frequency, according to one or more embodiments.

FIG. 7A illustrates a configuration for outputting a first component signal from a third signal and a fourth signal when a phase shifter operates at a center frequency, according to one or more embodiments.

FIG. 7B illustrates a configuration for outputting a second component signal from a fifth signal and a sixth signal when a phase shifter operates at a center frequency, according to one or more embodiments.

FIG. 7C illustrates a configuration for outputting an output signal from a first component signal and a second component signal when a phase shifter operates at a center frequency, according to one or more embodiments.

FIG. 8A illustrates a configuration for outputting a first component signal from a third signal and a fourth signal when a phase shifter operates at a second frequency, according to one or more embodiments.

FIG. 8B illustrates a configuration for outputting a second component signal from a fifth signal and a sixth signal when a phase shifter operates at a second frequency, according to one or more embodiments.

FIG. 8C illustrates a configuration for outputting an output signal from a first component signal and a second component signal when a phase shifter operates at a second frequency, according to one or more embodiments.

FIG. 9 is a flowchart showing an operating method of a phase shifter, according to one or more embodiments.

FIG. 10A is a flowchart illustrating a method in which a phase shifter outputs a first component signal, according to one or more embodiments.

FIG. 10B is a flowchart illustrating a method in which a phase shifter outputs a second component signal, according to one or more embodiments.

FIG. 11A illustrates a configuration for allowing a first component signal and a second component signal to have a specific phase difference, according to one or more embodiments.

FIG. 11B illustrates an output signal output when a first component signal and a second component signal have a specific phase difference, according to one or more embodiments.

FIG. 11C illustrates phase errors of a first component signal, a second component signal, and an output signal, according to one or more embodiments.

FIG. 12 is a block diagram showing a phase shifter, according to one or more embodiments.

FIG. 13 is a block diagram showing a phase shifter, according to one or more embodiments.

FIG. 14 is a block diagram showing a wireless communication device, according to one or more embodiments.

FIG. 15 is a block diagram illustrating an IoT device including an electronic device, according to one or more embodiments.

FIG. 16 is a block diagram showing a mobile terminal, to which an electronic device according to one or more embodiments is applied.

### DETAILED DESCRIPTION

Hereinafter, embodiments will be described in detail and clearly to such an extent that an ordinary one in the art easily implements the present disclosure. The embodiments described herein are non-limiting example embodiments, and thus, the disclosure is not limited thereto and may be realized in various other forms.

As used herein, expressions such as “first,” “second,” and the like may refer to various components regardless of order and/or importance, and are only used to distinguish one component from another and do not limit the order or importance of the components. As used herein, an expression, “a and/or b” should be understood as including only a, only b and both a and b. As used herein, expressions “at least one of a, b, and c” and “at least one of a, b, or c” should be understood as including only a, only b, only c, both a and b, both a and c, both b and c, or all of a, b, and c.

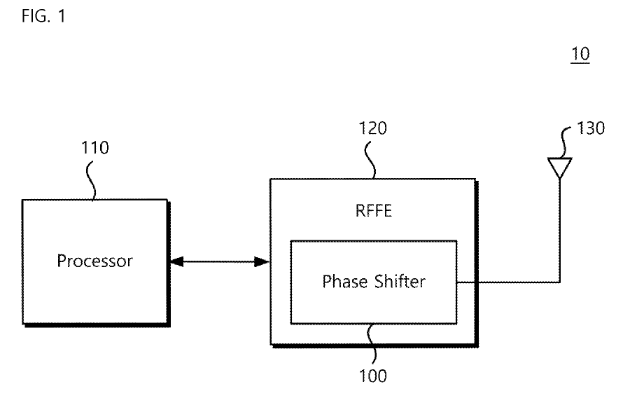

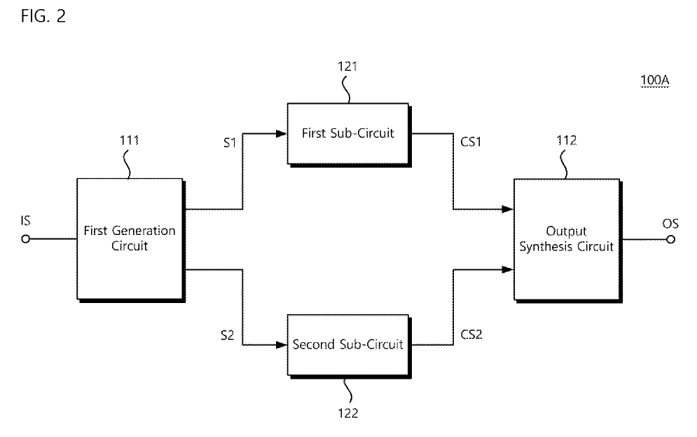

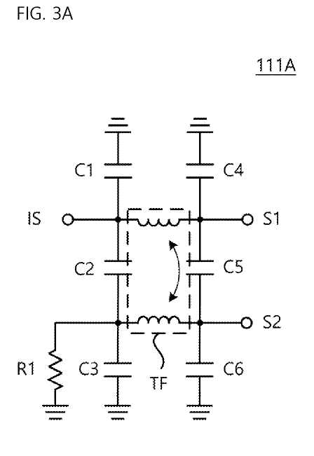

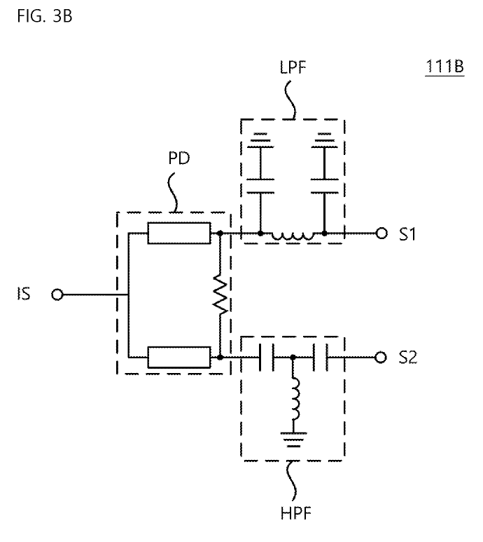

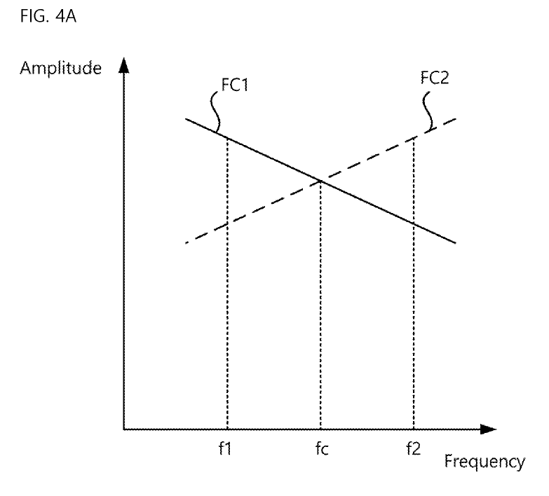

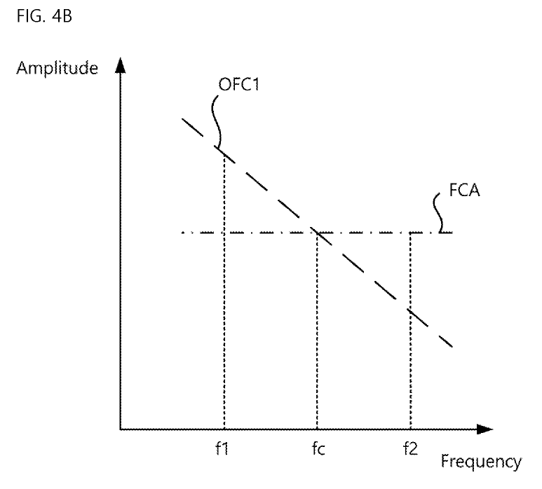

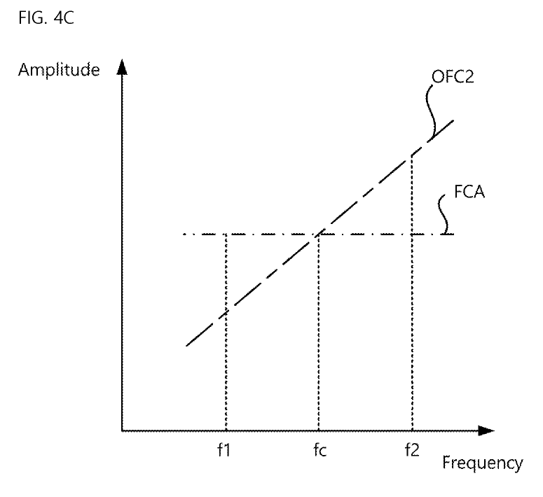

FIG. 1 is a block diagram illustrating an electronic device, according to one or more embodiments. FIG. 2 is a block diagram showing a phase shifter, according to one or more embodiments. FIG. 3A is a circuit diagram showing an example of a first generation circuit in a phase shifter. FIG. 3B is a circuit diagram showing another example of a first generation circuit in a phase shifter. FIG. 4A is a graph showing a first frequency response and a second frequency response, according to one or more embodiments. FIG. 4B is a graph showing a first overlapping frequency response and an offset frequency response, according to one or more embodiments. FIG. 4C is a graph showing a second overlapping frequency response and an offset frequency response, according to one or more embodiments.

Referring to FIG. 1, an electronic device 10 according to one or more embodiments may include a processor 110, a radio frequency front end (RFFE) 120, and an antenna 130.

The electronic device 10 according to various embodiments may be implemented by various types of devices. The electronic device 10 may be or include, for example, a portable communication device (e.g., a smartphone), a computer device, a portable multimedia device, a mobile medical appliance, a camera, or a wearable device. However, the electronic device 10 may not be limited to these examples.

The electronic device 10 may include the antenna 130 for transmitting and receiving a radio frequency (RF) signal having a specified frequency. Accordingly, the electronic device 10 according to the present embodiments may also be referred to as a “wireless transceiver”, a “wireless communication device”, or an “antenna device” including the antenna 130.

According to one or more embodiments, the antenna 130 may be referred to as an “array antenna” including a plurality of antenna elements. For example, the antenna 130 may include a plurality of antenna elements which transmit respective signals with different phases (or delays). In this way, the antenna 130 may transmit a beam signal that is propagated in a specified direction.

The electronic device 10 may include the processor 110 that controls operations of the electronic device 10.

For example, the processor 110 may execute software (or a program) to control at least one component (e.g., the RFFE 120) of the electronic device 10 and may process and calculate various types of data. The processor 110 may include a central processing device or a microprocessor, and may control an overall operation of the electronic device 10. Accordingly, below, operations performed by the electronic device 10 may be understood as being performed under the control of the processor 110.

According to one or more embodiments, the processor 110 may include an algorithm for controlling the RFFE 120 (or a phase shifter 100). For example, the algorithm may be or implemented by a software code programmed inside the processor 110 using internal memory or external memory. Additionally or alternatively, the algorithm may be or implemented by a hard code, which is hard-coded inside the processor 110 using internal memory or external memory, but is not limited thereto.

The processor 110 may provide a signal and/or power for transmitting an RF signal to the antenna 130 by controlling the RFFE 120 according to an algorithm. For example, the processor 110 may provide transmission power to the antenna 130 via the RFFE 120. In this way, the processor 110 may transmit and/or receive signals in a specified frequency band via the antenna 130.

Accordingly, the processor 110 may be a communication processor (CP), according to one or more embodiments.

The electronic device 10 may include the RFFE 120 connected between the processor 110 and the antenna 130. Here, the RFFE 120 may include at least some of an amplifier, a band pass filter, and a mixer.

Moreover, according to one or more embodiments, the RFFE 120 may include the phase shifter 100. For example, the RFFE 120 may include the phase shifter 100 that changes a phase of a signal delivered from the processor 110 to the antenna 130.

Referring to FIG. 2, a phase shifter 100A may convert a phase of an input signal IS and may output the phase-shifted input signal as an output signal OS, according to one or more embodiments. Here, the phase shifter 100A illustrated in FIG. 2 may be understood as an example of the phase shifter 100 illustrated in FIG. 1.

Moreover, the input signal IS may be understood as a signal whose frequency is up-converted by the processor 110 or a radio frequency integrated circuit (RFIC) connected between the processor 110 and the RFFE 120.

For example, the phase shifter 100A may generate a first signal S1 and a second signal S2 having different phases from the input signal IS. Furthermore, the phase shifter 100A may amplify the first signal S1 and the second signal S2. In addition, the phase shifter 100A may combine the amplified signals and output them as the output signal OS.

Here, the phase shifter 100A may control a phase of the output signal OS by controlling an amplification ratio (or an amplification gain) for signals with different phases. Accordingly, the phase shifter 100A according to the present embodiments may be referred to as a “vector sum phase shifter (VSPS)”.

Referring to FIG. 2, the phase shifter 100A may include a first generation circuit 111, a first sub-circuit 121, a second sub-circuit 122, and an output combining circuit 112.

For example, the phase shifter 100A may include the first generation circuit 111 that generates the first signal S1 and the second signal S2 from the input signal IS. Here, for example, the first signal S1 and the second signal S2 may have a phase difference of 90 degrees from each other. Accordingly, the first signal S1 and the second signal S2 may be referred to as an “I signal” and a “Q signal”. For example, the first generation circuit 111 may output the first signal S1 and the second signal S2, which are orthogonal to each other, from the input signal IS.

Referring to FIG. 3A, a first generation circuit 111A according to one or more embodiments may include a plurality of capacitors C1 to C6, a resistor R, and at least one transformer TF.

Referring to FIG. 3B, a first generation circuit 111B according to one or more other embodiment may include a power divider circuit PD, a low pass filter LPF, and a high pass filter HPF.

For example, the first generation circuit 111B may include the power divider circuit PD that distributes power of the input signal IS. Also, the first generation circuit 111B may include the low pass filter LPF that outputs signals, a frequency of each of the signals being less than a threshold frequency, from among signals output from the power divider circuit PD. Moreover, the first generation circuit 111B may include the high pass filter HPF that outputs signals, a frequency of each of the signals being greater than or equal to the threshold frequency, from among the signals output from the power divider circuit PD.

Here, each of the first generation circuit 111A illustrated in FIG. 3A and the first generation circuit 111B illustrated in FIG. 3B may be understood as an example of the first generation circuit 111 illustrated in FIG. 2.

Referring to FIG. 2, each of the input signal IS, the first signal S1, and the second signal S2 according to one or more embodiments may be a differential signal. For example, each of the input signal IS, the first signal S1, and the second signal S2 may include signals having a phase difference of 180 degrees from each other. Accordingly, the first generation circuit 111 may be referred to as a “differential coupler circuit”.

Referring to FIGS. 3A, 3B, and 4A together, the first signal S1 and the second signal S2 may have different frequency responses, according to one or more embodiments.

For example, the first signal S1 may have a first frequency response FC1 whose amplitude is inversely proportional to the magnitude of the operating frequency of the phase shifter 100A. Accordingly, the first frequency response FC1 may be referred to as a “low-pass response”.

Furthermore, the second signal S2 may have a second frequency response FC2 whose amplitude is proportional to the magnitude of the operating frequency of the phase shifter 100A. Accordingly, the second frequency response FC2 may be referred to as a “high-pass response”.

For example, when the phase shifter 100A operates at a first frequency f1 lower than a center frequency fc, the magnitude of the first signal S1 may be greater than that at a point in time when the phase shifter 100A operates at the center frequency fc. Also, for example, when the phase shifter 100A operates at the first frequency f1, the magnitude of the second signal S2 may be smaller than that at a point in time when the phase shifter 100A operates at the center frequency fc.

As another example, when the phase shifter 100A operates at a second frequency f2 higher than the center frequency fc, the magnitude of the first signal S1 may be smaller than that at a point in time when the phase shifter 100A operates at the center frequency fc. Also, for example, when the phase shifter 100A operates at the second frequency f2, the magnitude of the second signal S2 may be greater than that at a point in time when the phase shifter 100A operates at the center frequency fc.

Referring to the above-described configurations, the first generation circuit 111 may output the first signal S1 and the second signal S2, which have different frequency responses FC1 and FC2 and are orthogonal to each other, from the input signal IS.

Moreover, the phase shifter 100A may include the first sub-circuit 121 that generates a first component signal CS1 from the first signal S1.

Referring to FIGS. 2 and 4B together, the first sub-circuit 121 may generate the first component signal CS1 having a first overlapping frequency response OFC1, in which the first frequency response FC1 is overlapped, based on the first signal S1, according to one or more embodiments.

Here, the first overlapping frequency response OFC1 may be understood as a response in which the first frequency response FC1 is overlapped, and thus, a decrease in amplitude as the operating frequency of the phase shifter 100A increases is twice that of the first frequency response FC1.

Moreover, the phase shifter 100A may include the second sub-circuit 122 that generates a second component signal CS2 from the second signal S2.

Referring to FIGS. 2 and 4C together, the second sub-circuit 122 according to one or more embodiments may generate the second component signal CS2 having a second overlapping frequency response OFC2, in which the second frequency response FC2 is overlapped, based on the second signal S2.

Here, the second overlapping frequency response OFC2 may be understood as a response in which the second frequency response FC2 is overlapped, and thus, an increase in amplitude as the operating frequency of the phase shifter 100A increases is twice that of the second frequency response FC2.

Furthermore, referring to FIGS. 2-4C together, the phase shifter 100A may include the output combining circuit 112 that combines the first component signal CS1 and the second component signal CS2 and outputs the combined result as the output signal OS.

According to one or more embodiments, the output combining circuit 112 may combine the first component signal CS1 and the second component signal CS2 depending on a specified ratio. For example, the output combining circuit 112 may combine the first component signal CS1 and the second component signal CS2 in the ratio of 1:1. As another example, the output combining circuit 112 may combine the first component signal CS1 and the second component signal CS2 in the ratio of 2:1.

For example, the output combining circuit 112 may be implemented as one of a T-junction combiner, a Wilkinson combiner, a transformer-based parallel combiner, a transformer-based series combiner, and a 3-winding transformer. However, the configuration of the output combining circuit 112 is not limited to the examples described above.

Here, the output signal OS may have an offset frequency response FCA in which the first overlapping frequency response OFC1 and the second overlapping frequency response OFC2 are offset.

For example, referring to FIGS. 4B and 4C, the output signal OS may have a constant amplitude (or magnitude) regardless of the magnitude of the operating frequency of the phase shifter 100A.

Here, each of the first component signal CS1, the second component signal CS2, and the output signal OS may be a differential signal. For example, each of the first component signal CS1, the second component signal CS2, and the output signal OS may include two signals having a phase difference of 180 degrees from each other. Accordingly, the output combining circuit 112 may be referred to as a “differential power combiner”.

Referring to the above-described configurations, the phase shifter 100A may include the first generation circuit 111 that outputs, from the input signal IS, signals which have different frequency responses and are orthogonal to each other, according to one or more embodiments.

Moreover, the phase shifter 100A may include the sub-circuits 121 and 122 that output, from input signals, signals which have frequency responses in which frequency responses of the input signals are overlapped with each other, respectively.

Furthermore, the phase shifter 100A may include the output combining circuit 112, which combines signals with different frequency responses and outputs the output signal OS in which the different frequency responses are offset.

Through the above-described configurations, the phase shifter 100A may reduce influence of a change in the operating frequency of the phase shifter 100A on the magnitude of the output signal OS. For example, the phase shifter 100A may reduce errors caused by changes in the operating frequency of the phase shifter 100A. Here, the magnitude of a signal may refer to an amplitude of the signal.

Accordingly, the phase shifter 100A according to the present embodiments may improve the performance (e.g., resolution) of an operation of controlling a phase.

In addition, the phase shifter 100A according to the present embodiments may expand (or improve) the frequency band at which a phase is capable of being controlled.

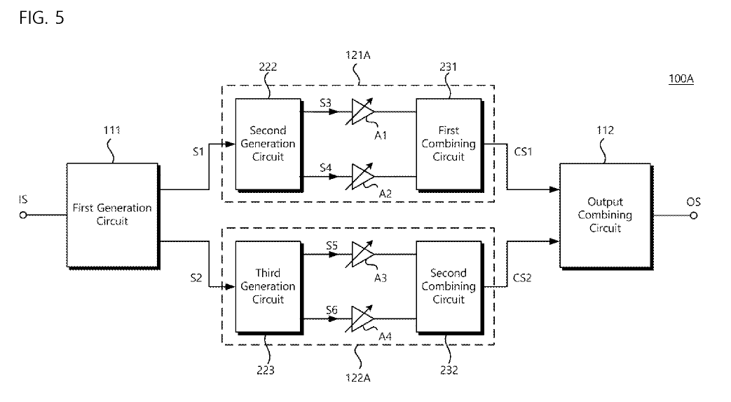

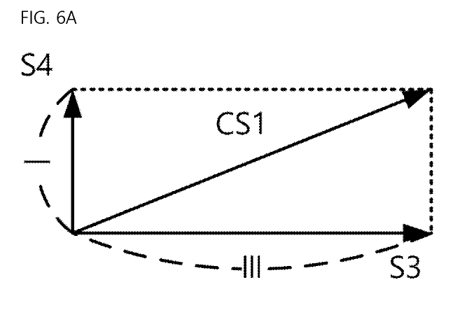

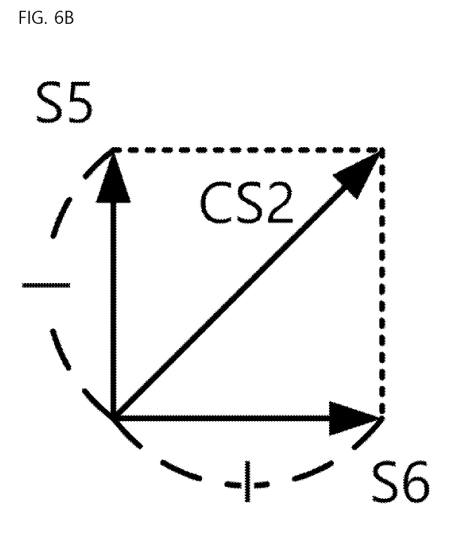

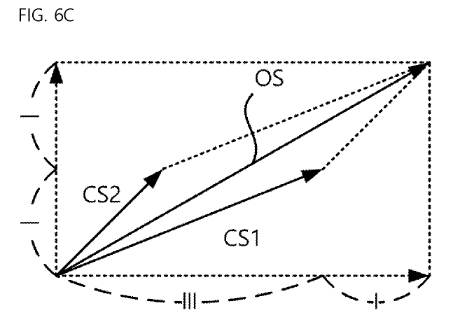

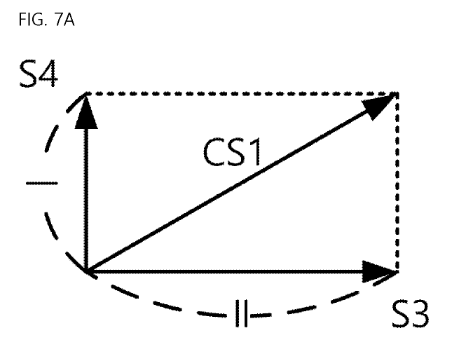

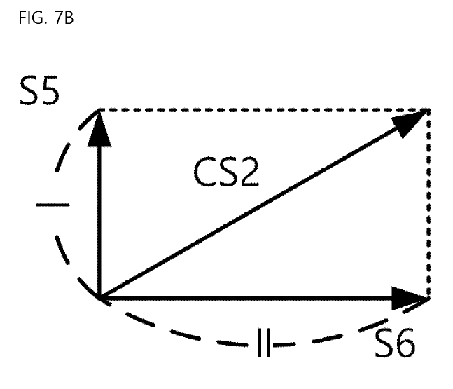

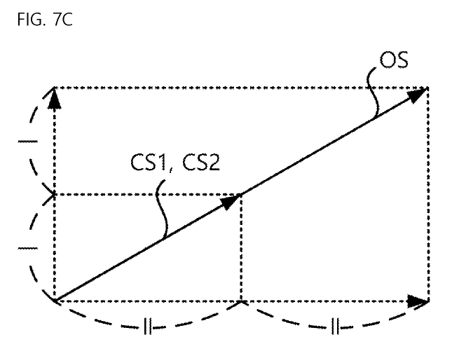

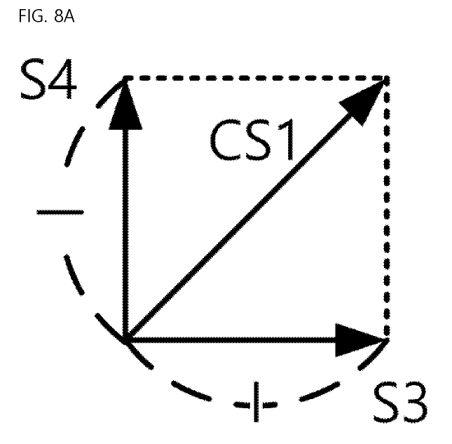

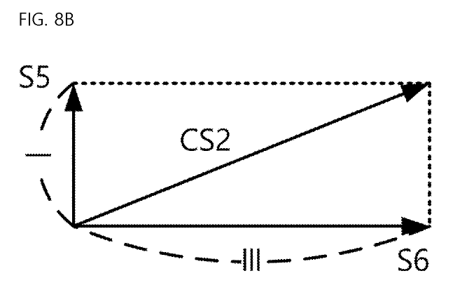

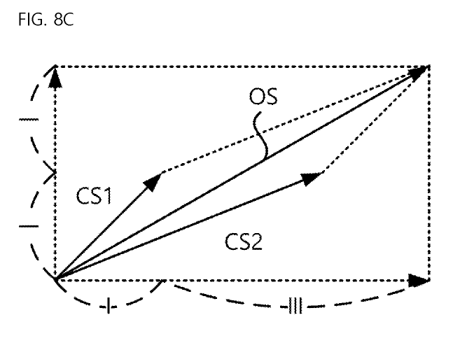

FIG. 5 is a circuit diagram showing a phase shifter, according to one or more embodiments. FIG. 6A illustrates a configuration for outputting a first component signal from a third signal and a fourth signal when a phase shifter operates at a first frequency, according to one or more embodiments. FIG. 6B illustrates a configuration for outputting a second component signal from a fifth signal and a sixth signal when a phase shifter operates at a first frequency, according to one or more embodiments. FIG. 6C illustrates a configuration for outputting an output signal from a first component signal and a second component signal when a phase shifter operates at a first frequency, according to one or more embodiments. FIG. 7A illustrates a configuration for outputting a first component signal from a third signal and a fourth signal when a phase shifter operates at a center frequency, according to one or more embodiments. FIG. 7B illustrates a configuration for outputting a second component signal from a fifth signal and a sixth signal when a phase shifter operates at a center frequency, according to one or more embodiments. FIG. 7C illustrates a configuration for outputting an output signal from a first component signal and a second component signal when a phase shifter operates at a center frequency, according to one or more embodiments. FIG. 8A illustrates a configuration for outputting a first component signal from a third signal and a fourth signal when a phase shifter operates at a second frequency, according to one or more embodiments. FIG. 8B illustrates a configuration for outputting a second component signal from a fifth signal and a sixth signal when a phase shifter operates at a second frequency, according to one or more embodiments. FIG. 8C illustrates a configuration for outputting an output signal from a first component signal and a second component signal when a phase shifter operates at a second frequency, according to one or more embodiments.

Referring to FIG. 5, a phase shifter 100A according to one or more embodiments may include the first generation circuit 111, a first sub-circuit 121A, a second sub-circuit 122A, and the output combining circuit 112.

Here, it may be understood that the phase shifter 100A illustrated in FIG. 5 has substantially the same configuration as the phase shifter 100A illustrated in FIG. 2. Moreover, the first sub-circuit 121A and the second sub-circuit 122A illustrated in FIG. 5 may be understood as examples of the first sub-circuit 121 and the second sub-circuit 122 illustrated in FIG. 2, respectively.

Accordingly, the same reference numerals are used for components the same or substantially the same as the above-described components, and descriptions the same as the above-described descriptions may be omitted.

According to one or more embodiments, the first sub-circuit 121A may include a second generation circuit 222, a first amplifier A1, a second amplifier A2, and a first combining circuit 231.

For example, the first sub-circuit 121A may include the second generation circuit 222 that outputs a third signal S3 and a fourth signal S4 based on the first signal S1.

Here, the third signal S3 and the fourth signal S4 may have a phase difference of 90 degrees and may be orthogonal to each other. Therefore, the third signal S3 and the fourth signal S4 may be referred to as an “I signal” and a “Q signal”, respectively.

Furthermore, the third signal S3 and the fourth signal S4 may have different frequency responses from each other.

For example, referring to FIGS. 4A, 4B, and 5 together, the third signal S3 may have the first overlapping frequency response OFC1 in which the first frequency response FC1 is overlapped. Accordingly, referring to FIGS. 6A, 7A, and 8A together, the magnitude of the third signal S3 may decrease from a size “III” to a size “I”, for example, in inversely proportional to the magnitude of the operating frequency of the phase shifter 100A.

Also, referring to FIGS. 4A, 4B, and 5 together, the fourth signal S4 may have the offset frequency response FCA in which the first frequency response FC1 and the second frequency response FC2 are offset. Accordingly, referring to FIGS. 6A, 7A, and 8A together, the magnitude of the fourth signal S4 may be uniformly maintained at the size “I”, for example, regardless of the magnitude of the operating frequency of the phase shifter 100A.

For example, the second generation circuit 222 may output, from the first signal S1, the third signal S3 and the fourth signal S4 which have different frequency responses and are orthogonal to each other.

Accordingly, the second generation circuit 222 may be understood as having substantially the same configuration as the first generation circuit 111. For example, the second generation circuit 222 may have substantially the same configuration as the first generation circuit 111A illustrated in FIG. 3A or the first generation circuit 111B illustrated in FIG. 3B.

Besides, the first sub-circuit 121A may include the first amplifier A1 that amplifies the third signal S3. Also, the first sub-circuit 121A may include the second amplifier A2 that amplifies the fourth signal S4.

Here, a gain of each of the first amplifier A1 and the second amplifier A2 may be changed under control of a processor (e.g., the processor 110 of FIG. 1). Accordingly, each of the first amplifier A1 and the second amplifier A2 may be referred to as a “variable gain amplifier”.

Furthermore, the first sub-circuit 121A may include the first combining circuit 231 that combines the amplified third signal S3 and the amplified fourth signal S4 and outputs the combined result as the first component signal CS1.

For example, referring to FIGS. 5, 6A, 7A, and 8A together, the first combining circuit 231 may generate the first component signal CS1 through a vector sum between the third signal S3 and the fourth signal S4.

Accordingly, the phase shifter 100A (or the processor 110) may control the phase and/or the magnitude of the first component signal CS1 by controlling the gain of each of the first amplifier A1 and the second amplifier A2.

Referring to FIGS. 6A, 7A, and 8A together, the first component signal CS1 may have a frequency response whose magnitude varies depending on the operating frequency of the phase shifter 100A due to the third signal S3 having the first overlapping frequency response OFC1. For example, the first component signal CS1 may have the first overlapping frequency response OFC1 due to the third signal S3 having the first overlapping frequency response OFC1.

For example, the magnitude of the first component signal CS1 at a point in time when the phase shifter 100A operates at the first frequency f1 (e.g., FIG. 6A) may be greater than that at a point in time when the phase shifter 100A operates at the center frequency fc (e.g., FIG. 7A). Furthermore, the magnitude of the first component signal CS1 at a point in time when the phase shifter 100A operates at the second frequency f2 (e.g., FIG. 8A) may be smaller than that at a point in time when the phase shifter 100A operates at the center frequency fc (e.g., FIG. 7A).

According to one or more embodiments, the second sub-circuit 122A may include a third generation circuit 223 that outputs a fifth signal S5 and a sixth signal S6 based on the second signal S2.

Here, the fifth signal S5 and the sixth signal S6 may have a phase difference of 90 degrees and may be orthogonal to each other. Therefore, the fifth signal S5 and the sixth signal S6 may be referred to as an “I signal” and a “Q signal”, respectively.

Furthermore, the fifth signal S5 and the sixth signal S6 may have different frequency responses from each other. For example, referring to FIGS. 4A, 4C, and 5 together, the fifth signal S5 may have the offset frequency response FCA in which the first frequency response FC1 and the second frequency response FC2 are offset.

Accordingly, referring to FIGS. 6B, 7B, and 8B together, the magnitude of the fifth signal S5 may be uniformly maintained at the size “I”, for example, regardless of the magnitude of the operating frequency of the phase shifter 100A.

Moreover, the sixth signal S6 may have the second overlapping frequency response OFC2 in which the second frequency response FC2 is overlapped. Therefore, referring to FIGS. 6B, 7B, and 8B together, the magnitude of the sixth signal S6 may increase from the size “I” to the size “III”, for example, in proportion to the operating frequency of the phase shifter 100A.

For example, the third generation circuit 223 may output, from the second signal S2, the fifth signal S5 and the sixth signal S6 which have different frequency responses and are orthogonal to each other.

Accordingly, the third generation circuit 223 may be understood as having substantially the same configuration as the first generation circuit 111. For example, the third generation circuit 223 may have substantially the same configuration as the first generation circuit 111A illustrated in FIG. 3A or the first generation circuit 111B illustrated in FIG. 3B.

Also, the second sub-circuit 122A may include a third amplifier A3 that amplifies the fifth signal S5. The second sub-circuit 122A may further include a fourth amplifier A4 that amplifies the sixth signal S6.

Here, a gain of each of the third amplifier A3 and the fourth amplifier A4 may be changed under control of a processor (e.g., the processor 110 of FIG. 1). Accordingly, each of the third amplifier A3 and the fourth amplifier A4 may be referred to as a “variable gain amplifier”.

Furthermore, the second sub-circuit 122A may include a second combining circuit 232 that combines the amplified fifth signal S5 and the amplified sixth signal S6 and outputs the combined result as the second component signal CS2.

For example, referring to FIGS. 5, 6B, 7B, and 8B together, the second combining circuit 232 may generate the second component signal CS2 through a vector sum between the fifth signal S5 and the sixth signal S6.

Accordingly, the phase shifter 100A (or the processor 110) may control the phase and/or magnitude of the second component signal CS2 by controlling the gain of each of the third amplifier A3 and the fourth amplifier A4.

Referring to FIGS. 6B, 7B, and 8B together, the second component signal CS2 may have a frequency response whose magnitude varies depending on the operating frequency of the phase shifter 100A due to the sixth signal S6 having the second overlapping frequency response OFC2. For example, the second component signal CS2 may have the second overlapping frequency response OFC2 due to the sixth signal S6 having the second overlapping frequency response OFC2.

For example, the magnitude of the second component signal CS2 at a point in time when the phase shifter 100A operates at the first frequency f1 (e.g., FIG. 6B) may be smaller than that at a point in time when the phase shifter 100A operates at the center frequency fc (e.g., FIG. 7B). Furthermore, the magnitude of the second component signal CS2 at a point in time when the phase shifter 100A operates at the second frequency f2 (e.g., FIG. 8B) may be greater than that at a point in time when the phase shifter 100A operates at the center frequency fc (e.g., FIG. 7B).

Furthermore, referring to FIG. 5, the phase shifter 100A may include the output combining circuit 112 that combines the first component signal CS1 and the second component signal CS2 and outputs the combined result as the output signal OS.

Here, the magnitude of the output signal OS may be maintained regardless of the magnitude of the operating frequency of the phase shifter 100A, as the frequency responses of the first component signal CS1 and the second component signal CS2 are offset.

For example, even when the phase shifter 100A operates at the first frequency f1 (e.g., FIG. 6C) and when the phase shifter 100A operates at the second frequency f2 (e.g., FIG. 8C), the output signal OS may have the same phase and magnitude as when the phase shifter 100A operates at the center frequency fc (e.g., FIG. 7C).

Referring to the configurations described above, the phase shifter 100A may include the plurality of generation circuits 111, 222, and 223, which output orthogonal signals with different frequency responses from an input signal, according to one or more embodiments.

In addition, the phase shifter 100A may combine signals, which have different frequency responses after being output through the plurality of generation circuits, and may output the combined result as the output signal OS. Here, the output signal OS may have a constant magnitude regardless of the operating frequency of the phase shifter 100A.

In this way, the phase shifter 100A may reduce the influence of a change in the operating frequency of the phase shifter 100A on the magnitude of the output signal OS.

For example, the phase shifter 100A may reduce errors caused by changes in the operating frequency of the phase shifter 100A. In this way, the phase shifter 100A according to the present embodiments may improve the performance of an operation of controlling a phase.

In addition, through the above-described configurations, the phase shifter 100A according to the present embodiments may expand the frequency band at which a phase is capable of being controlled.

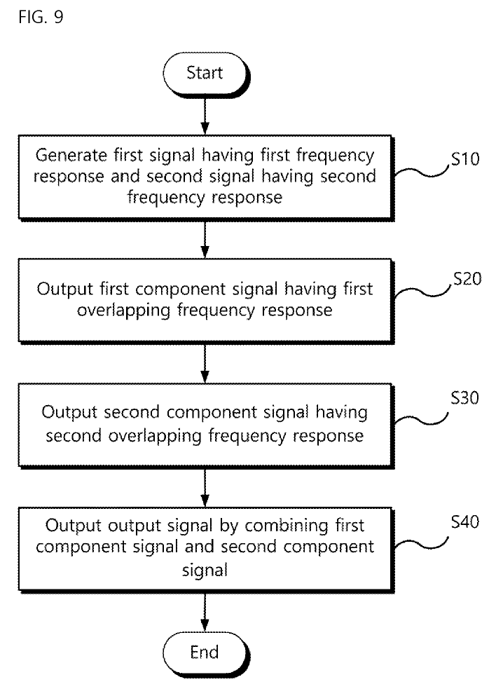

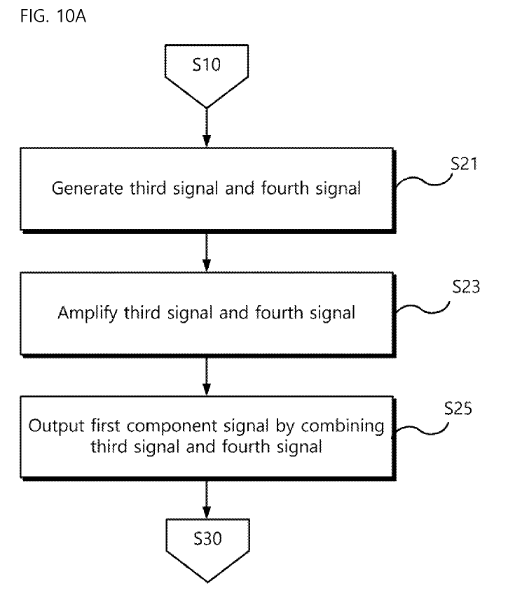

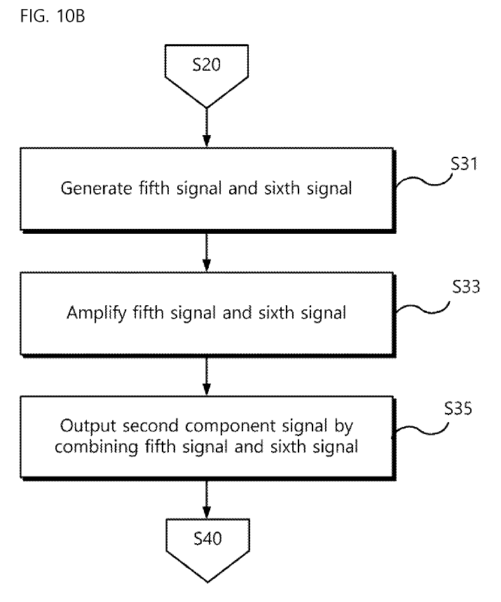

FIG. 9 is a flowchart showing an operating method of a phase shifter, according to one or more embodiments. FIG. 10A is a flowchart illustrating a method in which a phase shifter outputs a first component signal, according to one or more embodiments. FIG. 10B is a flowchart illustrating a method in which a phase shifter outputs a second component signal, according to one or more embodiments. The phase shifter described in reference to FIGS. 9 and 10 may be the phase shifter 100 shown in FIG. 1, and thus, the phase shifter 100 and its operations may be described in reference to FIGS. 9 and 10.

Referring to FIG. 9, the phase shifter 100may output the output signal OS having the specified phase and magnitude from the input signal IS, according to one or more embodiments.

For example, the phase shifter 100 may generate signals with different phases from the input signal IS. Furthermore, the phase shifter 100 may amplify each of the signals having different phases. Moreover, the phase shifter 100 may combine (or vector sum) the amplified signals and may output the combined result as the output signal OS.

Here, the phase shifter 100 may output the output signal OS for maintaining a magnitude regardless of the operating frequency of the phase shifter 100, by combining signals having different frequency responses.

In operation S10, the phase shifter 100 may generate the first signal S1 having the first frequency response FC1 and the second signal S2 having the second frequency response FC2, according to one or more embodiments.

For example, the phase shifter 100 (or the first generation circuit 111) may generate the first signal S1 having the first frequency response FC1 and the second signal S2 having the second frequency response FC2 from the input signal IS.

Here, the first signal S1 and the second signal S2 may have a phase difference of 90 degrees and may be orthogonal to each other. Therefore, the first signal S1 and the second signal S2 may be referred to as an “I signal” and a “Q signal”, respectively.

Also, here, the first frequency response FC1 may be a response in which the magnitude of a signal is inversely proportional to the operating frequency of the phase shifter 100. For example, the magnitude of the first signal S1 may decrease as the operating frequency of the phase shifter 100 increases.

Besides, the second frequency response FC2 may be a response in which the magnitude of a signal is proportional to the operating frequency of the phase shifter 100. For example, the magnitude of the second signal S2 may increase as the operating frequency of the phase shifter 100 increases.

In operation S20, the phase shifter 100 may output the first component signal CS1 having the first overlapping frequency response OFC1 in which the first frequency response FC1 is overlapped, according to one or more embodiments.

For example, the phase shifter 100 (or the first sub-circuit 121) may output the first component signal CS1 having the first overlapping frequency response OFC1 from the first signal S1.

Here, the first overlapping frequency response OFC1 may be understood as a response in which the first frequency response FC1 is overlapped and thus the decrease in amplitude as the operating frequency of the phase shifter 100 increases is twice that of the first frequency response FC1.

Referring to FIG. 10A, in operation S21, the phase shifter 100 (or the second generation circuit 222) may output the third signal S3 and the fourth signal S4 based on the first signal S1, according to one or more embodiments.

Here, the third signal S3 and the fourth signal S4 may have a phase difference of 90 degrees and may be orthogonal to each other.

Furthermore, the third signal S3 and the fourth signal S4 may have different frequency responses from each other.

For example, the third signal S3 may have the first overlapping frequency response OFC1 in which the first frequency response FC1 is overlapped. Accordingly, the magnitude of the third signal S3 may be inversely proportional to the magnitude of the operating frequency of the phase shifter 100.

Moreover, the fourth signal S4 may have the offset frequency response FCA in which the first frequency response FC1 and the second frequency response FC2 are offset. Accordingly, the magnitude of the fourth signal S4 may be uniformly maintained regardless of the magnitude of the operating frequency of the phase shifter 100.

In operation S23, the phase shifter 100 may amplify the third signal S3 and the fourth signal S4, according to one or more embodiments.

The phase shifter 100 may control the gain for amplifying the third signal S3 and the fourth signal S4. For example, the phase shifter 100 (or the processor 110) may control the gain for amplifying the third signal S3 through an amplifier (e.g., the first amplifier A1) placed in a path through which the third signal S3 is output.

In operation S25, the phase shifter 100 may output the first component signal CS1 by combining the amplified third signal S3 and the amplified fourth signal S4, according to one or more embodiments. For example, the phase shifter 100 may output the first component signal CS1 through a vector sum between the third signal S3 and the fourth signal S4.

The first component signal CS1 may have a frequency response whose magnitude decreases depending on the operating frequency of the phase shifter 100 due to the third signal S3 having the first overlapping frequency response OFC1. For example, the first component signal CS1 may have the first overlapping frequency response OFC1.

When the phase shifter 100 operates at the first frequency f1 lower than the center frequency fc, the magnitude of the first component signal CS1 may be greater than that at a point in time when the phase shifter 100 operates at the center frequency fc. Moreover, when the phase shifter 100 operates at the second frequency f2 higher than the center frequency fc, the magnitude of the first component signal CS1 may be smaller than that at a point in time when the phase shifter 100 operates at the center frequency fc.

Returning to FIG. 9, in operation S30, the phase shifter 100 may output the second component signal CS2 having the second overlapping frequency response OFC2 in which the second frequency response FC2 is overlapped, according to one or more embodiments.

For example, the phase shifter 100 (or the second sub-circuit 122) may output the second component signal CS2 having the second overlapping frequency response OFC2 from the second signal S2.

Here, the second overlapping frequency response OFC2 may be understood as a response in which the second frequency response FC2 is overlapped and thus the change amount of the amplitude according to the change amount of a frequency is twice that of the second frequency response FC2.

Referring to FIG. 10B, in operation S31, the phase shifter 100 (or the third generation circuit 223) may output the fifth signal S5 and the sixth signal S6 based on the second signal S2, according to one or more embodiments.

Here, the fifth signal S5 and the sixth signal S6 may have a phase difference of 90 degrees and may be orthogonal to each other.

Furthermore, the fifth signal S5 and the sixth signal S6 may have different frequency responses from each other.

For example, the fifth signal S5 may have the offset frequency response FCA in which the first frequency response FC1 and the second frequency response FC2 are offset. Accordingly, the magnitude of the fifth signal S5 may be uniformly maintained regardless of the magnitude of the operating frequency of the phase shifter 100.

For example, the sixth signal S6 may have the second overlapping frequency response OFC2 in which the second frequency response FC2 is overlapped. Accordingly, the magnitude of the sixth signal S6 may be proportional to the magnitude of the operating frequency of the phase shifter 100.

In operation S33, the phase shifter 100 may amplify the fifth signal S5 and the sixth signal S6, according to one or more embodiments.

The phase shifter 100 may control the gain for amplifying the fifth signal S5 and the sixth signal S6. For example, the phase shifter 100 (or the processor 110) may control the gain for amplifying the fifth signal S5 through an amplifier (e.g., the third amplifier A3) placed in a path through which the fifth signal S5 is output.

In operation S35, the phase shifter 100 may output the second component signal CS2 by combining the amplified fifth signal S5 and the amplified sixth signal S6, according to one or more embodiments. For example, the phase shifter 100 may output the second component signal CS2 through a vector sum between the fifth signal S5 and the sixth signal S6.

The second component signal CS2 may have a frequency response whose magnitude increases depending on the operating frequency of the phase shifter 100 due to the sixth signal S6 having the second overlapping frequency response OFC2. For example, the second component signal CS2 may have the second overlapping frequency response OFC2.

When the phase shifter 100 operates at the first frequency f1 lower than the center frequency fc, the magnitude of the second component signal CS2 may be smaller than that at a point in time when the phase shifter 100 operates at the center frequency fc. Moreover, when the phase shifter 100 operates at the second frequency f2 higher than the center frequency fc, the magnitude of the second component signal CS2 may be greater than that at a point in time when the phase shifter 100 operates at the center frequency fc.

Here, the phase shifter 100 (or the processor 110) may control the phases of the first component signal CS1 and the second component signal CS2 such that the first component signal CS1 and the second component signal CS2 have a phase difference that is an integer multiple of a minimum phase difference, according to one or more embodiments.

For example, the phase shifter 100 may control the gain of each of the amplifiers A1 to A4 such that the first component signal CS1 and the second component signal CS2 have a phase difference that is an integer multiple of the minimum phase difference.

Here, for example, the minimum phase difference may be referred to as the minimum phase difference between the first component signal CS1 and the second component signal CS2 that are controllable through the first to fourth amplifiers A1 to A4.

In this way, the phase shifter 100 according to the above embodiments may improve the performance (e.g., resolution) of an operation of controlling a phase.

Returning to FIG. 9, in operation S40, the phase shifter 100 may combine the first component signal CS1 and the second component signal CS2 and output the combined result as the output signal OS, according to one or more embodiments.

For example, the phase shifter 100 (or the output combining circuit 112) may combine the first component signal CS1 and the second component signal CS2, which have different frequency responses, and may output the combined result as the output signal OS.

Here, the magnitude of the output signal OS may be maintained regardless of the magnitude of the operating frequency of the phase shifter 100, as the frequency responses of the first component signal CS1 and the second component signal CS2 are offset.

Referring to the above-described configurations, the phase shifter 100 may output, from the input signal IS, signals which have different frequency responses and are orthogonal to each other.

In addition, the phase shifter 100 may combine signals, which have different frequency responses, and may output the combined result as the output signal OS. Here, the output signal OS may have a constant magnitude regardless of the operating frequency of the phase shifter 100.

In this way, the phase shifter 100 may reduce the influence of a change in the operating frequency of the phase shifter 100 on the magnitude of the output signal OS.

For example, the phase shifter 100 may reduce errors caused by changes in the operating frequency of the phase shifter 100. In this way, the phase shifter 100 according to the present embodiments may improve the performance of an operation of controlling a phase.

In addition, through the above-described configurations, the phase shifter 100 according to the present embodiments may expand the frequency band at which a phase is capable of being controlled.

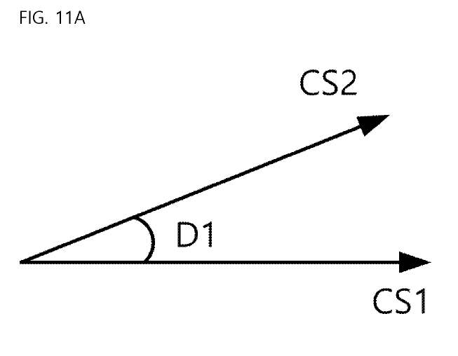

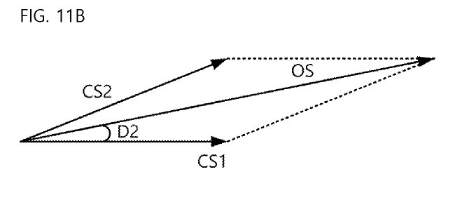

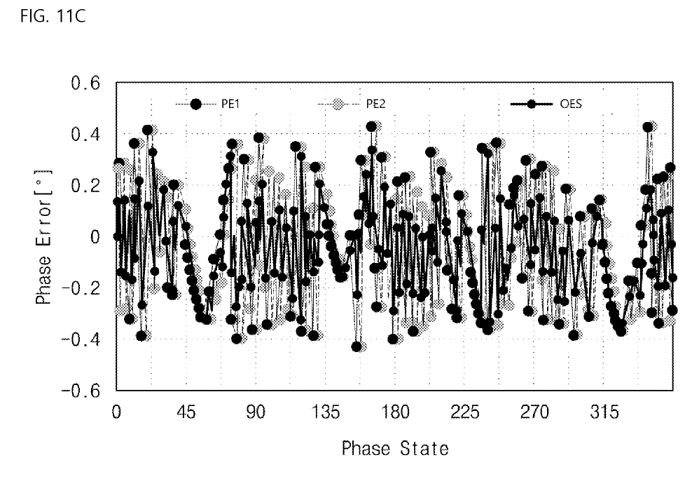

FIG. 11A illustrates a configuration for allowing a first component signal and a second component signal to have a specific phase difference in a phase shifter, according to one or more embodiments. FIG. 11B illustrates an output signal output when a first component signal and a second component signal have a specific phase difference in a phase shifter, according to one or more embodiments. FIG. 11C illustrates phase errors of a first component signal, a second component signal, and an output signal in a phase shifter, according to one or more embodiments. The phase shifter described in reference to FIGS. 11A-11C may be the phase shifter 100 shown in FIG. 1, and thus, the phase shifter 100 and its operations may be described in reference to FIGS. 11A-11C.

Referring to FIG. 11A, the phase shifter 100 (or the processor 110) may allow the first component signal CS1 and the second component signal CS2 to have a phase difference that is a specific phase difference, according to one or more embodiments.

For example, the phase shifter 100 may control the gain of each of the first to fourth amplifiers A1 to A4 such that the first component signal CS1 and the second component signal CS2 have a first phase difference D1.

Here, the first phase difference D1 may be referred to as a minimum phase difference between the first component signal CS1 and the second component signal CS2 that are controllable through the first to fourth amplifiers A1 to A4.

For example, the phase shifter 100 may control the gain of each of the first to fourth amplifiers A1 to A4 such that the first component signal CS1 and the second component signal CS2 have a minimum phase difference capable of being controlled through the first to fourth amplifiers A1 to A4.

Referring to FIG. 11B, the output signal OS may have a second phase difference D2 that is half of the first phase difference D1 from the first component signal CS1, according to one or more embodiments.

For example, the phase shifter 100 (or the output combining circuit 112) may output the output signal OS having the second phase difference D2 from the first component signal CS1 through the vector sum between the first component signal CS1 and the second component signal CS2.

For example, referring to the above-described configurations, the phase shifter 100 may output the output signal OS having a phase difference equal to half of the minimum phase difference, which is controllable through the first to fourth amplifiers A1 to A4, from the first component signal CS1, according to one or more embodiments.

In this way, the phase shifter 100 according to the present embodiments may improve the resolution of an operation of controlling a phase.

Moreover, according to one or more other embodiments, the first phase difference D1 illustrated in FIG. 11A may be referred to as an integer multiple of the minimum phase difference between the first component signal CS1 and the second component signal CS2, which are controllable through the first to fourth amplifiers A1 to A4.

For example, the phase shifter 100 may control the gain of each of the first to fourth amplifiers A1 to A4 such that the first component signal CS1 and the second component signal CS2 have a phase difference that is an integer multiple of the minimum phase difference controllable through the first to fourth amplifiers A1 to A4.

For example, the phase shifter 100 may control the gain of each of the first to fourth amplifiers A1 to A4 such that the first component signal CS1 and the second component signal CS2 have a phase difference that is twice the minimum phase difference controllable through the first to fourth amplifiers A1 to A4.

As another example, the phase shifter 100 may control the gain of each of the first to fourth amplifiers A1 to A4 such that the first component signal CS1 and the second component signal CS2 have a phase difference that is three times the minimum phase difference controllable through the first to fourth amplifiers A1 to A4.

Furthermore, the phase shifter 100 (or the output combining circuit 112) may combine the first component signal CS1 and the second component signal CS2, which have a phase difference that is an integer multiple of the minimum phase difference, and may output the combined result as the output signal OS.

Here, referring to FIG. 11C, the first component signal CS1 may have a first phase error PE1 according to the phase state of the first component signal CS1. Moreover, the second component signal CS2 may have a second phase error PE2 depending on the phase state of the second component signal CS2.

Furthermore, the output signal OS may have an output phase error OES corresponding to the average of the first phase error PE1 and the second phase error PE2.

Here, the output phase error OES may have a maximum value less than a value of each of the first phase error PE1 and the second phase error PE2.

For example, referring to the above-described configurations, the phase shifter 100 according to present embodiments may control the first component signal CS1 and the second component signal CS2 to have a phase difference that is an integer multiple of the minimum phase difference.

Furthermore, the phase shifter 100 may combine the first component signal CS1 and the second component signal CS2, which have a phase difference that is an integer multiple of the minimum phase difference, and may output the combined result as the output signal OS.

Here, the output signal OS may have the output phase error OES corresponding to the average of the phase errors PE1 and PE2 respectively corresponding to the first component signal CS1 and the second component signal CS2. Also, here, the output phase error OES may have the maximum value smaller than a value of each of the phase errors PE1 and PE2 respectively corresponding to the first component signal CS1 and the second component signal CS2.

Accordingly, through the above-described configurations, the phase shifter 100 according to the present embodiments may reduce the error of (e.g., the output phase error OES) the output signal OS. For example, the phase shifter 100 according to present embodiments may improve the resolution of an operation of controlling a phase.

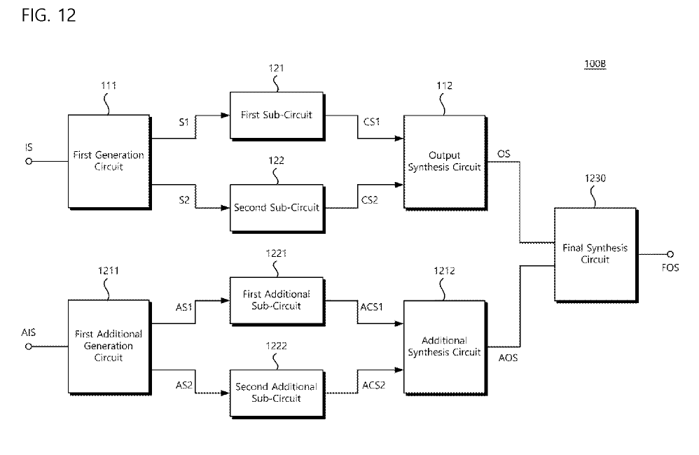

FIG. 12 is a block diagram showing a phase shifter, according to one or more embodiments.

Referring to FIG. 12, a phase shifter 100B may include the first generation circuit 111, the first sub-circuit 121, the second sub-circuit 122, the output combining circuit 112, a first additional generation circuit 1211, a first additional sub-circuit 1221, a second additional sub-circuit 1222, an additional combining circuit 1212, and a final combining circuit 1230.

Here, the phase shifter 100B illustrated in FIG. 12 may be understood as an example of the phase shifter 100 illustrated in FIG. 1. Additionally, the phase shifter 100B illustrated in FIG. 12 may include configurations substantially identical to those of the phase shifter 100A illustrated in FIG. 2.

Accordingly, the same reference numerals are used for components the same or substantially the same as the above-described components, and descriptions the same as the above-described descriptions may be omitted.

According to one or more embodiments, the phase shifter 100B may include the first additional generation circuit 1211 that outputs a first additional signal AS1 and a second additional signal AS2 from an additional input signal AIS.

Here, the additional input signal AIS may be determined as a signal having the same phase and magnitude as the input signal IS. For example, the additional input signal AIS and the input signal IS may be understood as signals generated after one signal passes through a power divider circuit.

Here, for example, the first additional signal AS1 and the second additional signal AS2 may have a phase difference of 90 degrees from each other. Accordingly, the first additional signal AS1 and the second additional signal AS2 may be referred to as an “I signal” and a “Q signal”. For example, the first additional generation circuit 1211 may output the first additional signal AS1 and the second additional signal AS2, which are orthogonal to each other from the input signal IS.

According to one or more embodiments, each of the additional input signal AIS, the first additional signal AS1, and the second additional signal AS2 may be a differential signal. For example, each of the additional input signal AIS, the first additional signal AS1, and the second additional signal AS2 may include signals having a phase difference of 180 degrees from each other. Accordingly, the first additional generation circuit 1211 may be referred to as a “differential coupler circuit”.

According to one or more embodiments, the first additional signal AS1 and the second additional signal AS2 may have different frequency responses from each other.

For example, the first additional signal AS1 may have the first frequency response FC1 whose amplitude is inversely proportional to the magnitude of the operating frequency of the phase shifter 100B.

Furthermore, the second additional signal AS2 may have the second frequency response FC2 whose amplitude is proportional to the magnitude of the operating frequency of the phase shifter 100B.

For example, when the phase shifter 100B operates at the first frequency f1 lower than the center frequency fc, the magnitude of the first additional signal AS1 may be greater than that at a point in time when the phase shifter 100B operates at the center frequency fc. Also, for example, when the phase shifter 100B operates at the first frequency f1, the magnitude of the second additional signal AS2 may be smaller than that at a point in time when the phase shifter 100B operates at the center frequency fc.

As another example, when the phase shifter 100B operates at the second frequency f2 higher than the center frequency fc, the magnitude of the first additional signal AS1 may be smaller than that at a point in time when the phase shifter 100B operates at the center frequency fc. Also, for example, when the phase shifter 100B operates at the second frequency f2, the magnitude of the second additional signal AS2 may be greater than that at a point in time when the phase shifter 100B operates at the center frequency fc.

Referring to the above-described configurations, the first additional generation circuit 1211 may output the first additional signal AS1 and the second additional signal AS2, which have different frequency responses FC1 and FC2 and are orthogonal to each other, from the additional input signal AIS. Accordingly, the first additional generation circuit 1211 may include substantially the same configuration as the first generation circuit 111.

Moreover, the phase shifter 100B may include the first additional sub-circuit 1221 that generates a first additional component signal ACS1 from the first additional signal AS1.

The first additional sub-circuit 1221 according to one or more embodiments may generate the first additional component signal ACS1 having the first overlapping frequency response OFC1, in which the first frequency response FC1 is overlapped, based on the first additional signal AS1.

Here, the first overlapping frequency response OFC1 may be understood as a response in which the first frequency response FC1 is overlapped, and thus, the decrease in amplitude as the operating frequency of the phase shifter 100B increases is twice that of the first frequency response FC1.

Here, the first additional sub-circuit 1221 may include substantially the same configuration as the first sub-circuit 121.

Moreover, the phase shifter 100B may include the second additional sub-circuit 1222 that generates a second additional component signal ACS2 from the second additional signal AS2.

The second additional sub-circuit 1222 according to one or more embodiments may generate the second additional component signal ACS2 having the second overlapping frequency response OFC2, in which the second frequency response FC2 is overlapped, based on the second additional signal AS2.

Here, the second overlapping frequency response OFC2 may be understood as a response in which the second frequency response FC2 is overlapped, and thus, the increase in amplitude as the operating frequency of the phase shifter 100B increases is twice that of the second frequency response FC2.

Here, the second additional sub-circuit 1222 may include substantially the same configuration as the second sub-circuit 122.

Furthermore, the phase shifter 100B may include the additional combining circuit 1212 that combines the first additional component signal ACS1 and the second additional component signal ACS2 and outputs the combined result as an additional output signal AOS.

According to one or more embodiments, the additional combining circuit 1212 may combine the first additional component signal ACS1 and the second additional component signal ACS2 depending on a specified ratio. For example, the additional combining circuit 1212 may combine the first additional component signal ACS1 and the second additional component signal ACS2 in the ratio of 1:1. As another example, the additional combining circuit 1212 may combine the first additional component signal ACS1 and the second additional component signal ACS2 in the ratio of 2:1.

Here, the additional combining circuit 1212 may include substantially the same configuration as the output combining circuit 112.

Moreover, the additional output signal AOS may have the offset frequency response FCA in which the first overlapping frequency response OFC1 and the second overlapping frequency response OFC2 are offset. For example, the additional output signal AOS may have a constant amplitude (or magnitude) regardless of the magnitude of the operating frequency of the phase shifter 100B.

Here, each of the first additional component signal ACS1, the second additional component signal ACS2, and the additional output signal AOS may be a differential signal. For example, each of the first additional component signal ACS1, the second additional component signal ACS2, and the additional output signal AOS may include two signals having a phase difference of 180 degrees from each other. Accordingly, the additional combining circuit 1212 may be referred to as a “differential power combiner”.

Furthermore, the phase shifter 100B may include the final combining circuit 1230 that combines the output signal OS and the additional output signal AOS and outputs the combined result as a final output signal FOS.

Referring to the configurations described above, the phase shifter 100B according to one or more embodiments may include configurations that output a signal (e.g., the output signal OS or the additional output signal AOS) whose frequency response is offset through configurations that are substantially identical to each other.

According to another embodiment, the phase shifter 100B may further include substantially the same configuration as the phase shifter 100A illustrated in FIG. 2. For example, the phase shifter 100B may include a configuration in which a plurality of circuits are connected in parallel and are substantially the same as the phase shifter 100A illustrated in FIG. 2.

Through the above-described configurations, the phase shifter 100B according to the present embodiments may expand the frequency band at which a phase is capable of being controlled.

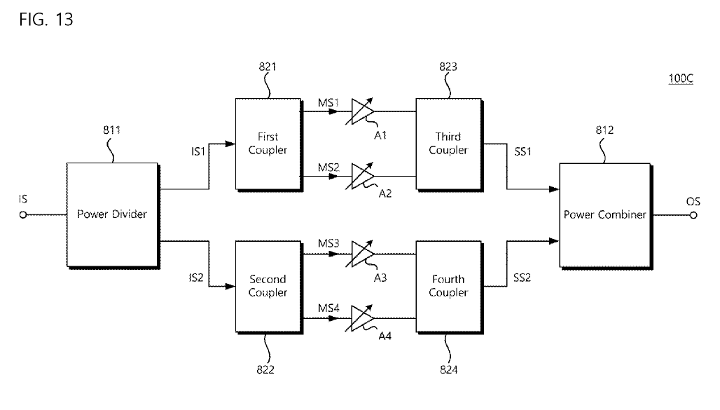

FIG. 13 is a block diagram showing a phase shifter, according to one or more embodiments.

Referring to FIG. 13, a phase shifter 100C according to one or more embodiments may include a power divider circuit 811, a first coupler circuit 821, a second coupler circuit 822, a third coupler circuit 823, a fourth coupler circuit 824, and a power combiner 812.

Here, the phase shifter 100C illustrated in FIG. 13 may be understood as an example of the phase shifter 100 illustrated in FIG. 1.

The phase shifter 100C may include the power divider circuit 811 which outputs a first input signal IS1 and a second input signal IS2 by dividing the power of the input signal IS.

For example, the power divider circuit 811 may output the first input signal IS1 and the second input signal IS2 having the same phase and magnitude (or power), by dividing the power of the input signal IS.

Moreover, the phase shifter 100C may include the first coupler circuit 821 which outputs a first middle signal MS1 having the first frequency response FC1 and a second middle signal MS2 having the second frequency response FC2 from the first input signal IS1.

Here, the first middle signal MS1 and the second middle signal MS2 may have a phase difference of 90 degrees and may be orthogonal to each other. Therefore, the first middle signal MS1 and the second middle signal MS2 may be referred to as an “I signal” and a “Q signal”, respectively.

Also, here, the first frequency response FC1 may be a response in which the magnitude of a signal is inversely proportional to the operating frequency of the phase shifter 100C. For example, the magnitude of the first middle signal MS1 may decrease as the operating frequency of the phase shifter 100C increases.

Besides, the second frequency response FC2 may be a response in which the magnitude of a signal is proportional to the operating frequency of the phase shifter 100C. For example, the magnitude of the second middle signal MS2 may increase as the operating frequency of the phase shifter 100C increases.

Here, each of the first input signal IS1, the first middle signal MS1, and the second middle signal MS2 may be a differential signal. For example, each of the first input signal IS1, the first middle signal MS1, and the second middle signal MS2 may include signals having a phase difference of 180 degrees from each other. Accordingly, the first coupler circuit 821 may be referred to as a “differential coupler circuit”.

Furthermore, the phase shifter 100C may include the second coupler circuit 822 which outputs a third middle signal MS3 having the first frequency response FC1 and a fourth middle signal MS4 having the second frequency response FC2 from the second input signal IS2.

Here, the third middle signal MS3 and the fourth middle signal MS4 may have a phase difference of 90 degrees and may be orthogonal to each other. Therefore, the third middle signal MS3 and the fourth middle signal MS4 may be referred to as an “I signal” and a “Q signal”, respectively.

Also, here, the first frequency response FC1 may be a response in which the magnitude of a signal is inversely proportional to the operating frequency of the phase shifter 100C. For example, the magnitude of the third middle signal MS3 may decrease as the operating frequency of the phase shifter 100C increases.

Besides, the second frequency response FC2 may be a response in which the magnitude of a signal is proportional to the operating frequency of the phase shifter 100C. For example, the magnitude of the fourth middle signal MS4 may increase as the operating frequency of the phase shifter 100C increases.

Here, each of the second input signal IS2, the third middle signal MS3, and the fourth middle signal MS4 may be a differential signal. For example, each of the second input signal IS2, the third middle signal MS3, and the fourth middle signal MS4 may include signals having a phase difference of 180 degrees from each other. Accordingly, the second coupler circuit 822 may be referred to as a “differential coupler circuit”.

According to one or more embodiments, each of the first coupler circuit 821 and the second coupler circuit 822 may include at least one transformer. For example, each of the first coupler circuit 821 and the second coupler circuit 822 may include substantially the same configuration as the first generation circuit 111A illustrated in FIG. 3A. For example, each of the first coupler circuit 821 and the second coupler circuit 822 may be referred to as a “transformer-based coupler circuit”.

The phase shifter 100C may include the first amplifier A1 that amplifies the first middle signal MS1. Besides, the phase shifter 100C may include the second amplifier A2 that amplifies the second middle signal MS2. Moreover, the phase shifter 100C may include the third amplifier A3 that amplifies the third middle signal MS3. Furthermore, the phase shifter 100C may include the fourth amplifier A4 that amplifies the fourth middle signal MS4.

Here, the gain of each of the first to fourth amplifiers A1 to A4 may be changed under control of a processor (e.g., the processor 110 of FIG. 1). Accordingly, each of the first to fourth amplifiers A1 to A4 may be referred to as a “variable gain amplifier”.

Moreover, the phase shifter 100C may include the third coupler circuit 823 which outputs a first combination signal SS1 from the amplified first middle signal MS1 and the amplified second middle signal MS2.

For example, the third coupler circuit 823 may combine the amplified first middle signal MS1 and the amplified second middle signal MS2 and may output the first combination signal SS1 having the offset frequency response FCA in which the first frequency response FC1 and the second frequency response FC2 are offset.

Furthermore, the phase shifter 100C may include the fourth coupler circuit 824 which outputs a second combination signal SS2 from the amplified third middle signal MS3 and the amplified fourth middle signal MS4.

For example, the fourth coupler circuit 824 may combine the amplified third middle signal MS3 and the amplified fourth middle signal MS4 and may output the second combination signal SS2 having the offset frequency response FCA, in which the first frequency response FC1 and the second frequency response FC2 are offset.

Accordingly, the phase shifter 100C (or the processor 110) may control the phase and magnitude of each of the first combination signal SS1 and the second combination signal SS2 by controlling the gain of each of the first to fourth amplifiers A1 to A4.

For example, the phase shifter 100C (or the processor 110) may control the phase and magnitude of the first combination signal SS1 by controlling the gain of each of the first amplifier A1 and the second amplifier A2.

Besides, the phase shifter 100C (or the processor 110) may control the phase and magnitude of the second combination signal SS2 by controlling the gain of each of the third amplifier A3 and the fourth amplifier A4.

For example, the phase shifter 100C (or the processor 110) may control the gain of each of the first to fourth amplifiers A1 to A4 such that the first combination signal SS1 and the second combination signal SS2 have a phase difference that is an integer multiple of the minimum phase difference. Here, the minimum phase difference may be understood as the minimum phase difference controllable through the first to fourth amplifiers A1 to A4.

Furthermore, the phase shifter 100C may include the power combiner 812 that combines the first combination signal SS1 and the second combination signal SS2 and outputs the combined result as the output signal OS.

For example, the power combiner 812 may output the output signal OS having the offset frequency response FCA through the vector sum between the first combination signal SS1 and the second combination signal SS2.

Referring to the configurations described above, the phase shifter 100C may include the plurality of coupler circuits 821 and 822, each of which outputs orthogonal signals with different frequency responses, according to one or more embodiments.

Moreover, the phase shifter 100C may include the plurality of coupler circuits 823 and 824, each of which combines signals having different frequency responses and outputs a signal having the offset frequency response FCA.

Furthermore, the phase shifter 100C may include the power combiner 812 which combines signals having the offset frequency response FCA and outputs the output signal OS. Here, the output signal OS may have a constant magnitude regardless of the operating frequency of the phase shifter 100C.

In this way, the phase shifter 100C may reduce the influence of a change in the operating frequency of the phase shifter 100C on the magnitude of the output signal OS.

For example, the phase shifter 100C may reduce errors caused by changes in the operating frequency of the phase shifter 100C. In this way, the phase shifter 100C according to the present embodiments may improve the performance of an operation of controlling a phase.

In addition, through the above-described configurations, the phase shifter 100C according to the present embodiments may expand the frequency band at which a phase is capable of being controlled.

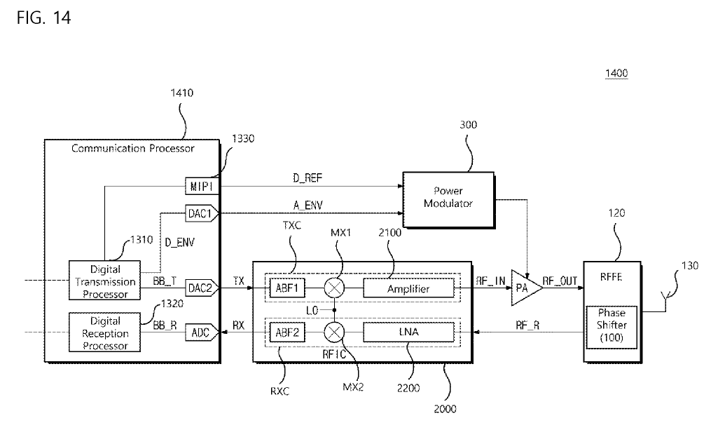

FIG. 14 is a block diagram showing a wireless communication device, according to one or more embodiments.

Referring to FIG. 14, a wireless communication device 1400 according to one or more embodiments may include a communication processor 1410, an RFIC 2000, a power modulator 300, the RFFE 120, a power amplifier PA, and the antenna 130.

Here, the wireless communication device 1400 illustrated in FIG. 14 and a configuration thereof may be understood as an example of the electronic device 10 illustrated in FIG. 1 and a configuration thereof. Accordingly, the same reference numerals are used for components the same or substantially the same as the above-described components, and descriptions the same as the above-described descriptions may be omitted.

The communication processor 1410 may process a baseband signal BB_T through a digital transmission processor 1310 in compliance with a given communication scheme. Furthermore, the communication processor 1410 may process a received baseband signal BB_R through a digital reception processor 1320 in compliance with the given communication scheme.

Here, the communication processor 1410 may be understood as having substantially the same configuration as the processor 110 illustrated in FIG. 1.

For example, the communication processor 1410 may process a signal to be transmitted or a received signal in compliance with a communication scheme such as orthogonal frequency division multiplexing (OFDM), orthogonal frequency division multiplexing access (OFDMA), wideband code multiple access (WCDMA), or high speed packet access+ (HSPA+). Besides, the communication processor 1410 may process the baseband signal BB_T or BB_R in compliance with various kinds of communication schemes (i.e., various communication schemes to which a technology for modulating or demodulating the amplitude and the frequency of the baseband signal BB_T or BB_R is applied).

The communication processor 1410 may extract an envelope of the baseband signal BB_T through the digital transmission processor 1310 and may generate a digital envelope signal D_ENV based on the extracted envelope. Moreover, the communication processor 1410 may generate an average power signal D_REF based on an average power tracking table stored in a memory. Here, the extracted envelope may correspond to an amplitude component (i.e., a magnitude of the I signal and the Q signals) of the baseband signal BB_T.

Here, the communication processor 1410 may perform digital-to-analog conversion on the baseband signal BB_T and the digital envelope signal D_ENV by using a plurality of digital-to-analog converters DAC1 and DAC2 included therein and may generate a transmit signal TX and an analog envelope signal A_ENV being analog signals. For example, the average power signal D_REF output from the communication processor 1410 may be a digital signal. As such, the average power signal D_REF may be provided to a digital-to-analog converter included in the power modulator 300 through a MIPI 1330 and may be converted into an analog signal, for example, the reference voltage signal through the digital-to-analog converter included in the power modulator 300. In one or more embodiments, the digital-to-analog converters DAC1 and DAC2 included in the communication processor 1410 may operate at a speed higher than the digital-to-analog converter included in the power modulator 300.

However, the present disclosure is not limited thereto. For example, the communication processor 1410 may convert the average power signal D_REF into an analog signal through a digital-to-analog converter included therein and may output the analog signal. In this case, the communication processor 1410 may provide average power signal converted into the analog signal as a reference voltage signal to the power modulator 300.

However, for convenience of description, in the embodiments, the description will be given as the communication processor 1410 provides the average power signal D_REF to the digital-to-analog converter included in the power modulator 300 through the MIPI 1330.

In one or more embodiments, each of the transmit signal TX and the analog envelope signal A_ENV may be implemented as differential signals including a positive signal and a negative signal.

Also, the communication processor 1410 may be provided with a receive signal RX being an analog signal from the RFIC 2000. Moreover, the communication processor 1410 may perform analog-to-digital conversion on the receive signal RX through an analog-to-digital converter ADC included therein and may extract the baseband signal BB_R being a digital signal. Here, the receive signal RX may be implemented as differential signals including a positive signal and a negative signal.

The RFIC 2000 may generate an RF input signal RF_IN by performing frequency up-conversion on the transmit signal TX or may generate the receive signal RX by performing frequency down-conversion on an RF receive signal RF_R. In detail, the RFIC 2000 may include a transmission circuit TXC for frequency up-conversion, a reception circuit RXC for frequency down-conversion, and a local oscillator LO.

Here, the transmission circuit TXC may include a first analog baseband filter ABF1, a first mixer MX1, and an amplifier 2100. For example, the first analog baseband filter ABF1 may include a low pass filter.

The first analog baseband filter ABF1 may filter the transmit signal TX received from the communication processor 1410 so as to be provided to the first mixer MX1. Furthermore, the first mixer MX1 may perform frequency up-conversion for converting a frequency of the transmit signal TX from a baseband to a high-frequency band through a frequency signal provided by the local oscillator LO. The transmit signal TX obtained through the frequency up-conversion may be provided to the amplifier 2100 as the RF input signal RF_IN, and the amplifier 2100 may first amplify a power of the RF input signal RF_IN so as to be provided to the power amplifier PA.

The power amplifier PA may be supplied with a power supply voltage (i.e., a dynamically variable output voltage) from the power modulator 300, may secondarily amplify a power of the RF input signal RF_IN based on the supplied power supply voltage, and may generate an RF output signal RF_OUT. The power amplifier PA may provide the generated RF output signal RF_OUT thus generated to the RFFE 120.

The reception circuit RXC may include a second analog baseband filter ABF2, a second mixer MX2, and a low-noise amplifier 2200. For example, the second analog baseband filter ABF2 may include a low pass filter.

The low-noise amplifier 2200 may amplify the RF receive signal RF_R provided from the RFFE 120 to provide the amplified RF receive signal RF_R to the second mixer MX2. Moreover, the second mixer MX2 may perform frequency down-conversion for converting a frequency of the RF receive signal RF_R from a high-frequency band to a baseband through a frequency signal provided by the local oscillator LO. The RF receive signal RF_R may be provided to the second analog baseband filter ABF2 as the receive signal RX through the above frequency down-conversion, and the second analog baseband filter ABF2 may filter the receive signal RX to provide the filtered receive signal RX to the communication processor 1410.

The power modulator 300 may generate a modulated output voltage, the level of which varies dynamically, based on the analog envelope signal A_ENV and the average power signal D_REF and may provide the modulated output voltage to the power amplifier PA as a power supply voltage.

In detail, the power modulator 300 may be provided with the average power signal D_REF and the analog envelope signal A_ENV from the communication processor 1410. The power modulator 300 may be driven in the tracking mode corresponding to one of the ET mode and the APT mode based on the average power signal D_REF and the analog envelope signal A_ENV thus provided and may generate the dynamically variable output voltage. Also, the power modulator 300 may supply the generated output voltage to the power amplifier PA as the power supply voltage.

In one or more embodiments, when the power supply voltage of a fixed level is applied to the power amplifier PA, power efficiency of the power amplifier PA may decrease. Accordingly, to efficiently manage a power of the power amplifier PA, the power modulator 300 may modulate an input voltage (i.e., a power provided from a battery) based on at least one of the analog envelope signal A_ENV and the average power signal D_REF and may provide the modulated voltage to the power amplifier PA as the power supply voltage.

The wireless communication device 1400 may include the RFFE 120 connected to the antenna 130. In detail, the RFFE 120 may separate the RF output signal RF_OUT provided from the power amplifier PA for each frequency band to provide the separated RF output signal RF_OUT to the corresponding antenna 130. Also, the RFFE 120 may provide an external signal provided from the antenna 130 to the low-noise amplifier 2200 of the reception circuit RXC of the RFIC 2000. For example, the RFFE 120 may include a front end module with integrated duplexer (FEMiD).

Moreover, the RFFE 120 may further include the phase shifter 100. According to one or more embodiments, the phase shifter 100 may control the phase of the RF output signal RF_OUT transmitted from the RFIC 2000 so as to be provided to the antenna 130. Here, the RF output signal RF_OUT may be understood as a signal substantially the same as the input signal IS illustrated in FIG. 2.

According to one or more embodiments, the phase shifter 100 may include the first generation circuit 111 that outputs signals, which have different frequency responses and which are orthogonal to each other, from the input signal IS.

Moreover, the phase shifter 100 may include the sub-circuits 121 and 122 that output signals, which have frequency responses in which frequency responses of input signals are overlapped with each other, from the input signals.

Furthermore, the phase shifter 100 may include the output combining circuit 112, which combines signals with different frequency responses and outputs the output signal OS in which the different frequency responses are offset.

Through the above-described configurations, the phase shifter 100 may reduce the influence of a change in the operating frequency of the phase shifter 100 on the magnitude of the output signal OS. For example, the phase shifter 100 may reduce errors caused by changes in the operating frequency of the phase shifter 100. Accordingly, the phase shifter 100 according to present embodiments may improve the performance of an operation of controlling a phase.

In addition, the phase shifter 100 according to one or more embodiments may expand the frequency band at which a phase is capable of being controlled.

The antenna 130 may transmit the RF output signal RF_OUT to the outside or may provide the RF receive signal RF_R received from the outside to the RFIC 2000. For example, the antenna 130 may be referred to as an “array antenna” including a plurality of antenna elements.

In one or more embodiments, each of the communication processor 1410, the power modulator 300, the RFIC 2000, the power amplifier PA, and the RFFE 120 may be implemented as an integrated circuit, a chip, or a module. Also, the communication processor 1410, the power modulator 300, the RFIC 2000, the power amplifier PA, and the RFFE 120 may be together mounted on a printed circuit board (PCB). However, the technical idea is not limited thereto. In some embodiments, at least a part of the communication processor 1410, the power modulator 300, the RFIC 2000, the power amplifier PA, and the RFFE 120 may be implemented with a single communication chip.

In addition, the wireless communication device 1400 illustrated in FIG. 14 may be included in a wireless communication system that uses a cellular network such as 5G, LTE or the like and may also be included in a wireless local area network (WLAN) system or any other wireless communication system. In one or more embodiments, a configuration of the wireless communication device 1400 illustrated in FIG. 14 is, but is not limited to, one or more embodiments, and may be variously configured in compliance with a communication protocol or a communication scheme.

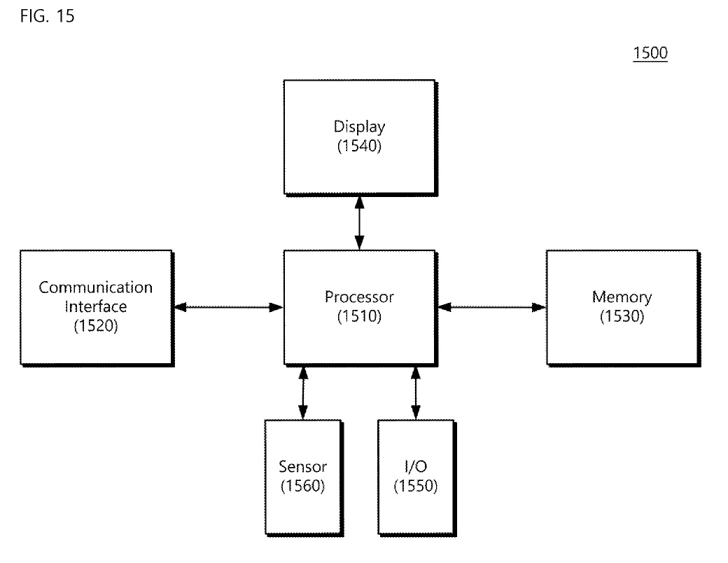

FIG. 15 is a block diagram illustrating an Internet of Things (IoT) device including an electronic device, according to one or more embodiments.

Referring to FIG. 15, IoT may refer to a network between things that use wired and/or wireless communication. An IoT device 1500 may include an accessible wired or/and wireless interface and may include devices that communicate with at least one or more other devices through the wired or/and wireless interface to transmit or receive data. The accessible interface that the IoT device 1500 includes may include a modem communication interface that is accessible to a local area network (LAN), a wireless local area network (WLAN) such as a wireless fidelity (Wi-Fi), a wireless personal area network (WPAN) such as Bluetooth, a wireless universal serial bus (USB), a Zigbee, a near field communication (NFC), a radio-frequency identification (RFID), a power line communication (PLC), or mobile cellular networks such as 3rd generation (3G), long term evolution (LTE), 4th generation (4G), or 5th generation (5G).

In detail, the IoT device 1500 may include a communication interface 1520 for communicating with the outside. The communication interface 1520 may be, for example, a modem communication interface that is accessible to a wireless local area network such as an LAN, Bluetooth, Wi-Fi, or Zeebee, PLC, a mobile communication network, such as 3G, LTE, 4G, or 5G, etc.

The IoT device 1500 according to one or more embodiments may be understood to include substantially the same configuration as the electronic device 10 illustrated in FIG. 1.

The communication interface 1520 may include a transmitter and/or a receiver. Here, the communication interface 1520 illustrated in FIG. 15 may be understood to include the RFFE 120 and the antenna 130 illustrated in FIG. 1.

According to one or more embodiments, the communication interface 1520 may further include the phase shifter 100. According to one or more embodiments, the phase shifter 100 may control the phase of a signal (e.g., the input signal IS) transmitted from a processor 1510 and provide the signal to the antenna 130.

According to one or more embodiments, the phase shifter 100 may include the first generation circuit 111 that outputs signals, which have different frequency responses and which are orthogonal to each other, from the input signal IS.

Moreover, the phase shifter 100 may include the sub-circuits 121 and 122 that output signals, which have frequency responses in which frequency responses of input signals are overlapped with each other, from the input signals.

Furthermore, the phase shifter 100 may include the output combining circuit 112, which combines signals with different frequency responses and outputs the output signal OS in which the different frequency responses are offset.

Through the above-described configurations, the phase shifter 100 may reduce the influence of a change in the operating frequency of the phase shifter 100 on the magnitude of the output signal OS. For example, the phase shifter 100 may reduce errors caused by changes in the operating frequency of the phase shifter 100. Accordingly, the phase shifter 100 according to the present embodiments may improve the performance of an operation of controlling a phase.

In addition, the phase shifter 100 according to the present embodiments may expand the frequency band at which a phase is capable of being controlled.

The IoT device 1500 may transmit and/or receive information from an access point or a gateway through the transmitter and/or the receiver. Also, the IoT device 1500 may communicate with a user apparatus or any other IoT device to transmit and/or receive control information or data of the IoT device 1500.

The IoT device 1500 may include the processor 1510 that performs arithmetic operations. Here, the processor 1510 illustrated in FIG. 15 may be referenced as a configuration substantially the same as the processor 110 illustrated in FIG. 1.

For internal power supply, the IoT device 1500 may further include an embedded battery or a power supply unit that is supplied with a power from the outside. Also, the IoT device 1500 may include a display 1540 for displaying an internal state or data. The user may control the IoT device 1500 through a user interface (UI) of the display 1540 in the IoT device 1500. The IoT device 1500 may transmit an internal state and/or data to the outside through the transmitter and may receive a control instruction and/or data from the outside through the receiver.

A memory 1530 may store a control instruction code controlling the IoT device 1500, control data, or user data. The memory 1530 may include at least one of a volatile memory or a nonvolatile memory. The nonvolatile memory includes at least one of various memories such as a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (ReRAM), and a ferroelectric RAM (FRAM). The volatile memory may include at least one of various memories such as a static RAM (SRAM), a dynamic RAM (DRAM), and a synchronous DRAM (SDRAM).

The IoT device 1500 may further include a storage device. The storage device may include at least one of nonvolatile media such as a solid state drive (SSD), an embedded multimedia card (eMMC), and universal flash storage (UFS). The storage device may store user information provided through an input/output unit (I/O) 1550 and pieces of sensing information collected through a sensor 1560.

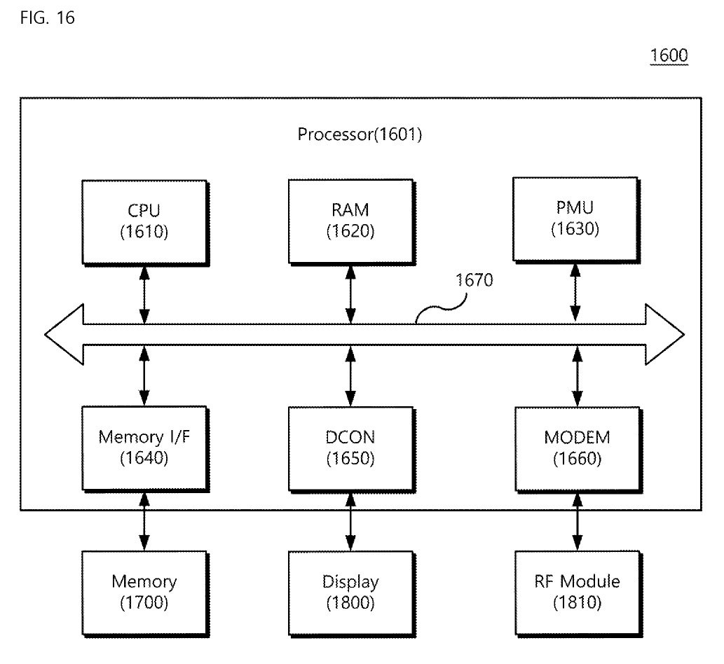

FIG. 16 is a block diagram showing a mobile terminal to which an electronic device according to one or more embodiments is applied.

Referring to FIG. 16, a mobile terminal 1600 may include a processor 1601, a memory 1700, a display 1800, and a radio frequency (RF) module 1810. In addition, the mobile terminal 1600 may further include various components such as a lens and an audio module.

The processor 1601 may be implemented as a system on chip (SoC) and may include a central processing unit (CPU) 1610, a RAM 1620, a power management unit (PMU) 1630, a memory interface (I/F) 1640, a display controller (DCON) 1650, a MODEM 1660, and a bus 1670. Besides, the processor 1601 may further include various intellectual properties (IPs). The processor 1601 may be integrated with a function of a MODEM chip therein, which is referred to as a “ModAP”, but is not limited thereto.

Here, the processor 1601 illustrated in FIG. 16 may be referenced as having substantially the same configuration as the processor 110 illustrated in FIG. 1.

The CPU 1610 may control overall operations of the processor 1601 and the mobile terminal 1600. The CPU 1610 may control an operation of each component of the processor 1601. Also, the CPU 1610 may be implemented as a multi-core. The multi-core may be one computing component having two or more independent cores.

The RAM 1620 may temporarily store programs, data, or instructions. For example, the programs and/or data stored in the memory 1700 may be temporarily stored in the RAM 1620 under control of the CPU 1610 or depending on a booting code. The RAM 1620 may be implemented with a DRAM or an SRAM.

The PMU 1630 may manage power of each component of the processor 1601. The PMU 1630 may also determine an operating situation of each component of the processor 1601 and may control an operation thereof.

The memory interface 1640 may control overall operations of the memory 1700 and may control data exchange of the memory 1700 with each component of the processor 1601. At the request of the CPU 1610, the memory interface 1640 may write data in the memory 1700 or may read data from the memory 1700.

The display controller 1650 may provide the display 1800 with image data to be displayed on the display 1800. The display 1800 may be implemented with a flat panel display, such as a liquid crystal display (LCD) or an organic light emitting diode (OLED) display, or a flexible display.

For wireless communication, the MODEM 1660 may modulate data to be transmitted so as to be appropriate for a wireless environment and may recover received data. The MODEM 1660 may perform digital communication with the RF module 1810.

According to one or more embodiments, the RF module 1810 may be electrically connected to the antenna 130 illustrated in FIG. 1. Moreover, the RF module 1810 may include the RFFE 120 illustrated in FIG. 1.

Accordingly, the RF module 1810 may convert a high-frequency signal received through the antenna 130 into a low-frequency signal and may transmit the converted low-frequency signal to the MODEM 1660. Also, the RF module 1810 may convert a low-frequency signal received from the MODEM 1660 into a high-frequency signal and may transmit the converted high-frequency signal to the outside of the mobile terminal 1600 through the antenna 130. The RF module 1810 may amplify or filter a signal.

According to one or more embodiments, the RF module 1810 may further include the phase shifter 100. According to one or more embodiments, the phase shifter 100 may control the phase of a signal (e.g., the input signal IS) transmitted from the processor 1601 and provide the signal to the antenna 130.

According to one or more embodiments, the phase shifter 100 may include the first generation circuit 111 that outputs signals, which have different frequency responses from the input signal IS and which are orthogonal to each other.

Moreover, the phase shifter 100 may include the sub-circuits 121 and 122 that output signals, which have frequency responses in which frequency responses of input signals are overlapped with each other, from the input signals.

Furthermore, the phase shifter 100 may include the output combining circuit 112, which combines signals with different frequency responses and outputs the output signal OS in which the different frequency responses are offset.

Through the above-described configurations, the phase shifter 100 may reduce the influence of a change in the operating frequency of the phase shifter 100 on the magnitude of the output signal OS. For example, the phase shifter 100 may reduce errors caused by changes in the operating frequency of the phase shifter 100. Accordingly, the phase shifter 100 according to one or more embodiments may improve the performance of an operation of controlling a phase.

In addition, the phase shifter 100 according to one or more embodiments may expand the frequency band at which a phase is capable of being controlled.

As described above, the phase shifter 100 according to the present embodiments may include the first generation circuit 111 that outputs signals, which have different frequency responses and which are orthogonal to each other, from the input signal IS.

Moreover, the phase shifter 100 may include the sub-circuits 121 and 122 that output signals, which have frequency responses in which frequency responses of input signals are overlapped with each other, from the input signals.

Furthermore, the phase shifter 100 may include the output combining circuit 112, which combines signals with different frequency responses and outputs the output signal OS in which the different frequency responses are offset. Here, the magnitude of the output signal OS may be maintained regardless of the magnitude of the operating frequency of the phase shifter 100.

Through the above-described configurations, the phase shifter 100 may reduce the influence of a change in the operating frequency of the phase shifter 100 on the magnitude of the output signal OS. For example, the phase shifter 100 may reduce errors caused by changes in the operating frequency of the phase shifter 100. Accordingly, the phase shifter 100 according to the present embodiments may improve the performance of an operation of controlling a phase.

In addition, the phase shifter 100 according to the present embodiments may expand the frequency band at which a phase is capable of being controlled.

Embodiments in which a design is changed simply or which are easily changed may be included in the present disclosure as well as one or more embodiments described above. In addition, technologies that are easily changed and implemented by using the above embodiments may be included in the present disclosure. Accordingly, it will be apparent to those of ordinary skill in the art that various changes and modifications may be made to the above embodiments without departing from the spirit and scope as set forth in the following claims.

A phase shifter according to the present embodiments may expand a frequency band in which phase control is possible.

While the present disclosure has been described with reference to the above embodiments thereof, it will be apparent to those of ordinary skill in the art that various changes and modifications may be made thereto without departing from the spirit and scope of the present disclosure as set forth in the following claims.

What is claimed is:

1. A phase shifter comprising:
a first generation circuit configured to output, from an input signal, a first signal having a first frequency response and a second signal having a second frequency response, the second signal being orthogonal to the first signal;
a first sub-circuit configured to output a first component signal having a first overlapping frequency response, in which the first frequency response is overlapped, based on the first signal;
a second sub-circuit configured to output a second component signal having a second overlapping frequency response, in which the second frequency response is overlapped, based on the second signal; and
an output combining circuit configured to combine the first component signal and the second component signal and to output an output signal in which the first overlapping frequency response and the second overlapping frequency response are offset.

2. The phase shifter of claim 1, wherein the first sub-circuit further comprises:
a second generation circuit configured to output, from the first signal, a third signal having the first overlapping frequency response, and a fourth signal having an offset frequency response, in which the first frequency response and the second frequency response are offset, the fourth signal being orthogonal to the third signal;
a first amplifier configured to amplify the third signal;
a second amplifier configured to amplify the fourth signal; and
a first combining circuit configured to combine the amplified third signal and the amplified fourth signal and to output the combined result as the first component signal.

3. The phase shifter of claim 2, wherein the second sub-circuit further comprises:
a third generation circuit configured to output, from the second signal, a fifth signal having the offset frequency response and a sixth signal having the second overlapping frequency response, the sixth signal being orthogonal to the fifth signal;
a third amplifier configured to amplify the fifth signal;
a fourth amplifier configured to amplify the sixth signal; and
a second combining circuit configured to combine the amplified fifth signal and the amplified sixth signal and to output the combined result as the second component signal.

4. The phase shifter of claim 3, further comprising:
a processor electrically connected to the first amplifier, the second amplifier, the third amplifier, and the fourth amplifier,
wherein the processor is configured to:
control a phase and a magnitude of the first component signal by controlling a gain of each of the first amplifier and the second amplifier; and
control a phase and a magnitude of the second component signal by controlling a gain of each of the third amplifier and the fourth amplifier.

5. The phase shifter of claim 4, wherein the processor is configured to:
control the gain of each of the first amplifier, the second amplifier, the third amplifier, and the fourth amplifier such that the first component signal and the second component signal have a phase difference that is an integer multiple of a minimum phase difference.

6. The phase shifter of claim 1, wherein the first frequency response is a response in which an amplitude of the first signal is inversely proportional to an operating frequency of the phase shifter, and
wherein the second frequency response is a response in which an amplitude of the second signal is proportional to the operating frequency.

7. The phase shifter of claim 1, wherein the first generation circuit comprises:
a power divider circuit configured to divide and output power of the input signal;
a low pass filter configured to output the first signal having the first frequency response among signals transmitted from the power divider circuit; and
a high pass filter configured to output the second signal having the second frequency response among signals transmitted from the power divider circuit.

8. The phase shifter of claim 1, further comprising:
a first additional generation circuit configured to output, from an additional input signal, a first additional signal having the first frequency response and a second additional signal having the second frequency response, the second additional signal being orthogonal to the first additional signal;
a first additional sub-circuit configured to output a first additional component signal having the first overlapping frequency response from the first additional signal;
a second additional sub-circuit configured to output a second additional component signal having the second overlapping frequency response from the second additional signal;
an additional combining circuit configured to combine the first additional component signal and the second additional component signal and to output an additional output signal in which the first overlapping frequency response and the second overlapping frequency response are offset; and
a final combining circuit configured to combine the output signal and the additional output signal and to output a final output signal.

9. The phase shifter of claim 1, wherein the output combining circuit configured to combine a signal obtained by multiplying the first component signal by a first power weight and a signal obtained by multiplying the second component signal by a second power weight.

10. The phase shifter of claim 1, wherein each of the input signal, the first signal, the second signal, the first component signal, the second component signal, and the output signal is a differential signal.

11. An operating method of a phase shifter, the method comprising:
generating, from an input signal input to a first generation circuit, a first signal having a first frequency response and a second signal having a second frequency response, the second signal being orthogonal to the first signal;
generating a first component signal having a first overlapping frequency response, in which the first frequency response is overlapped, based on the first signal;
generating a second component signal having a second overlapping frequency response, in which the second frequency response is overlapped, based on the second signal; and
combining the first component signal and the second component signal and outputting an output signal in which the first overlapping frequency response and the second overlapping frequency response are offset.

12. The method of claim 11, wherein the generating the first component signal based on the first signal further comprises:
outputting, from the first signal, a third signal having the first overlapping frequency response and a fourth signal having an offset frequency response, in which the first frequency response and the second frequency response are offset, the fourth signal being orthogonal to the third signal;
amplifying the third signal by controlling a first amplifier and amplifying the fourth signal by controlling a second amplifier; and
combining the amplified third signal and the amplified fourth signal and outputting the combined result as the first component signal.

13. The method of claim 12, wherein the generating the second component signal based on the second signal further comprises:
outputting, from the second signal, a fifth signal having the offset frequency response and a sixth signal having the second overlapping frequency response, the sixth signal being orthogonal to the fifth signal;
amplifying the fifth signal by controlling a third amplifier and amplifying the sixth signal by controlling a fourth amplifier; and
combining the amplified fifth signal and the amplified sixth signal and outputting the combined result as the second component signal.

14. The method of claim 13, further comprising:
controlling a gain of each of the first amplifier, the second amplifier, the third amplifier, and the fourth amplifier such that the first component signal and the second component signal have a phase difference that is an integer multiple of a minimum phase difference.

15. The method of claim 11, wherein the first frequency response is a response in which amplitude of the first signal is inversely proportional to an operating frequency of the phase shifter, and
wherein the second frequency response is a response in which amplitude of the second signal is proportional to the operating frequency.

16. A phase shifter comprising:
a power divider circuit configured to divide power of an input signal and to output a first input signal and a second input signal having a same phase;
a first coupler circuit configured to output, from the first input signal, a first middle signal having a first frequency response and a second middle signal having a second frequency response, the second middle signal being orthogonal to the first middle signal;
a second coupler circuit configured to output, from the second input signal, a third middle signal having the first frequency response and a fourth middle signal having the second frequency response, the fourth middle signal being orthogonal to the third middle signal;
a third coupler circuit configured to output, from the first middle signal and the second middle signal, a first combination signal having an offset frequency response in which the first frequency response and the second frequency response are offset;
a fourth coupler circuit configured to output a second combination signal having the offset frequency response from the third middle signal and the fourth middle signal; and
a power combiner configured to combine the first combination signal and the second combination signal and to output an output signal.

17. The phase shifter of claim 16, wherein the first frequency response is a response in which amplitude is inversely proportional to an operating frequency of the phase shifter, and
wherein the second frequency response is a response in which amplitude is proportional to the operating frequency.

18. The phase shifter of claim 16, further comprising:
a first amplifier configured to amplify the first middle signal;
a second amplifier configured to amplify the second middle signal;
a third amplifier configured to amplify the third middle signal;
a fourth amplifier configured to amplify the fourth middle signal; and
a processor electrically connected to the first amplifier, the second amplifier, the third amplifier, and the fourth amplifier,
wherein the processor is configured to:
control a phase and a magnitude of the first combination signal by controlling a gain of each of the first amplifier and the second amplifier; and
control a phase and a magnitude of the second combination signal by controlling a gain of each of the third amplifier and the fourth amplifier.

19. The phase shifter of claim 18, wherein the processor is configured to:
control the gain of each of the first amplifier, the second amplifier, the third amplifier, and the fourth amplifier such that the first combination signal and the second combination signal have a phase difference that is an integer multiple of a minimum phase difference.

20. The phase shifter of claim 16, wherein each of the first coupler circuit and the second coupler circuit comprises at least one transformer.
